(19) United States
(12) Patent Application Publication
(10) Pub. No.: US 2010/0244136 A1
(43) Pub. Date: Sep. 30, 2010

(54) SEMICONDUCTOR DEVICE, SINGLE-CRYSTAL SEMICONDUCTOR THIN FILM-INCLUDING SUBSTRATE, AND PRODUCTION METHODS THEREOF

(75) Inventors: Yutaka Takafuji, Osaka-shi (JP); Kazuo Nakagawa, Osaka-shi (JP); Yasumori Fukushima, Osaka-shi (JP); Kazuhide Tomiyasu, Osaka-shi (JP); Michiko Takei, Osaka-shi (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: Sharp Kabushiki Kaisha, Osaka-shi, Osaka (JP)

(21) Appl. No.: 12/742,660

(22) PCT Filed: Oct. 22, 2008
(86) PCT No.: PCT/JP2008/069159

§ 371 Date: May 13, 2010

(30) Foreign Application Priority Data
Dec. 27, 2007 (JP) 2007-337922

(51) Int. Cl. H01L 27/12; H01L 21/762

(52) U.S. Cl. 257/351; 438/458; 257/507; 257/E21.568; 257/E27.112

(57) ABSTRACT

The present invention provides a semiconductor device, a single-crystal semiconductor thin film-including substrate, and production methods thereof, each allowing single-crystal semiconductor thin film-including single-crystal semiconductor elements produced by being transferred onto a low heat resistant insulating substrate to have enhanced transistor characteristics and a reduced wiring resistance.

The present invention is a production method of a semiconductor device including single-crystal semiconductor thin film-including single-crystal semiconductor elements on an insulating substrate,

the production method including a heat treatment step of subjecting a single-crystal semiconductor thin film to a heat treatment at 650° C. or higher,

the single-crystal semiconductor thin film including at least part of each one of single-crystal semiconductor elements and boded to an intermediate substrate with a heat-resistant temperature higher than that of the insulating substrate.

### TECHNICAL FIELD

The present invention is directed to semiconductor devices, single-crystal semiconductor thin film-including substrates, and production methods thereof. More particularly, the present invention is directed to a semiconductor device and a single-crystal semiconductor thin film-including substrate each preferably used in display devices such as an LCD (liquid crystal display) device and an organic EL display device, and to production methods thereof.

### BACKGROUND ART

Semiconductor devices are electronic devices including active elements exploiting electric properties of semiconductor materials. Such semiconductor devices have been widely used in audio equipment, communication equipment, computers, electric appliances, and the like. Particularly, semiconductor devices including a three-terminal active element such as a MOS (metal oxide semiconductor) thin film transistor (hereinafter, also referred to as a “TFT”) are used as a pixel switching element arranged in each pixel, a pixel control circuit, and the like, in display devices such as an active matrix liquid crystal display device (hereinafter, also referred to as an “LC display”) and an organic electroluminescent display device (hereinafter, also referred to as a “organic EL display”).

Single-crystal semiconductor thin film-including substrates, which include a single-crystal semiconductor thin film on an insulating substrate, particularly, a SOI (silicon on insulator) substrate, which includes a single-crystal Si layer on an insulating layer, is being actively researched now.

For example, Non-patent Documents 1 and 2 relate to the Smart-Cut process developed by Bruel. According to the Smart-Cut process, a single-crystal silicon layer is transferred onto a substrate in the following manner: hydrogen or rare gas ions are implanted into a bulk silicon (Si) wafer; this wafer is attached to another substrate; a heat treatment is performed for cleavage of the hydrogen-implanted layer to cleave the wafer.

With respect to transfer of a semiconductor substrate to a substrate, a technology of bonding flat and hydrophilic oxide films to each other is being developed.

Further, with respect to transfer of a semiconductor substrate to a display device substrate, large-size substrates for active matrix display devices including single-crystal Si thin films closely arranged over the entire glass substrate in a tile pattern or disposed at portions of the glass substrate are also being developed.

For example, Non-patent Document 3 relates to thermal donor formation in Si.

### [Non-Patent Document 1]

M. Bruel (1995), “Silicon on insulator material technology”, Electronics Letters, vol. 31, No. 14, p. 1201 to 1202, U.S.

### [Non-Patent Document 2]

Michel Bruel, and three others (1997), “Smart-cut: A New Silicon On Insulator Material Technology Based on Hydrogen Implantation and Wafer Bonding,” Japanese Journal of Applied Physics, vol. 36, No. 3B, p. 1636 to 1641, Japan.

### [Non-Patent Document 3]

H. J. Stein, S. K. Hahn (1994), “Hydrogen introduction and hydrogen-enhanced thermal donor formation in silicon,” Journal of Applied Physics, vol. 75, No. 7, p. 3477 to 3484, U.S.

### DISCLOSURE OF INVENTION

According to the conventional technology involving only one transfer process, the implanted hydrogen ions might cause thermal donor formation or inactivation of acceptor boron (B) to deteriorate transistor characteristics. This occurs not when LSI technology allowing high-temperature heat treatments is employed but when low to medium temperature heat treatments are performed due to low heat resistance of glass substrates.

Further, surface roughness of the single-crystal Si thin film, i.e., uneven thickness of the film possibly causes a reduction or variation in transistor characteristics.

It is also difficult that single-crystal Si thin film-including single-crystal Si elements on which a low-resistance metal wiring has been formed are transferred onto an insulating substrate.

The present invention has been made in view of the above-mentioned state of the art. The present invention has an object to provide a semiconductor device, a single-crystal semiconductor thin film-including substrate, and production methods thereof, each allowing single-crystal semiconductor thin film-including single-crystal semiconductor elements produced by being transferred onto a low heat resistant insulating substrate to have enhanced transistor characteristics and a reduced wiring resistance.

The present inventors made various investigations on the above-mentioned semiconductor device, single-crystal semiconductor thin film-including substrate, and production methods thereof, and noted heat treatment for the single-crystal semiconductor thin film. The inventors found that curing of defects in the single-crystal semiconductor thin film, and suppression of thermal donor formation and activation of inactivated boron in the thin film are allowed, and the single-crystal semiconductor thin film transferred onto the insulating substrate can show a small surface roughness, and further, low-resistance metal materials can be used for wirings when the single-crystal semiconductor thin film is bonded to an intermediate substrate with a heat-resistant temperature higher than the low heat-resistant insulating substrate, and the thin film undergoes a heat treatment at 650° C. or higher even if the thin film is formed by being separated from a semiconductor substrate by cleavage of a cleavage substance containing hydrogen and/or rare gas ions-implanted layer formed in the semiconductor substrate. As a result, the above-mentioned problems have been admirably solved, leading to completion of the present invention.

The present invention relates to a production method of a semiconductor device including single-crystal semiconductor thin film-including single-crystal semiconductor elements on an insulating substrate,

the production method including a heat treatment step of subjecting a single-crystal semiconductor thin film to a heat treatment at 650° C. or higher,

the single-crystal semiconductor thin film including at least part of each one of single-crystal semiconductor elements and boded to an intermediate substrate with a heat-resistant temperature higher than that of the insulating substrate (hereinafter, also referred to as a “production method of the semiconductor device of the present invention”).

According to this production method, curing of defects in the single-crystal semiconductor thin film, and suppression of thermal donor formation and activation of inactivated acceptor (preferably, boron) in the thin film are allowed because a high-temperature heat treatment can be subjected to the single-crystal semiconductor thin film on the intermediate substrate excellent in heat resistance even if the thin film is formed by being separated from a semiconductor substrate by cleavage of a cleavage substance containing hydrogen and/or rare gas ions-implanted layer formed in the semiconductor substrate. As a result, the transistor characteristics can be improved. In addition, wirings can be formed after the single-crystal semiconductor thin film on the intermediate substrate excellent in heat resistance sufficiently undergoes the heat treatment, and further, low-resistance metal materials such as aluminum (Al) alloys with a low melting point can be used for the wirings.

The production method of the semiconductor device of the present invention is not especially limited as long as it involves the above-mentioned heat treatment step.

The present invention is also a production method of a single-crystal semiconductor thin film-including substrate including an insulating substrate and a single-crystal semiconductor thin film formed on the insulating substrate,

the production method including a heat treatment step of subjecting a single-crystal semiconductor thin film bonded to an intermediate substrate with a heat-resistant temperature higher than that of an insulating substrate to a heat treatment at 650° C. or higher (hereinafter, also referred to as a “production method of the single-crystal semiconductor thin film-including substrate of the present invention”).

Also according to this production method, the single-crystal semiconductor thin film on the intermediate substrate excellent in heat resistance undergoes the high-temperature heat treatment, and so curing of defects in the single-crystal semiconductor thin film, and suppression of thermal donor formation and activation of inactivated acceptor (preferably, boron) in the thin film are allowed even if the thin film is formed by being separated from a semiconductor substrate by cleavage of a cleavage substance containing hydrogen and/or rare gas ions-implanted layer formed in the semiconductor substrate. Further, a first transfer onto the intermediate substrate can be performed, and then, a second transfer onto the insulating substrate (final substrate) can be performed. This allows that the single-crystal semiconductor thin film can be arranged so that a cleavage layer-side surface thereof usually having low flatness is on the insulating substrate side and the other surface excellent in flatness is on the surface side. Specifically, the single-crystal semiconductor thin film with a low surface roughness can be arranged on the insulating substrate. As a result, the transistor characteristics can be improved. In addition, wirings can be formed after the single-crystal semiconductor thin film on the intermediate substrate excellent in heat resistance sufficiently undergoes the heat treatment, and further, low-resistance metal materials such as aluminum (Al) alloys with a low melting point can be used for the wirings.

The production method of the single-crystal semiconductor thin film-including substrate of the present invention is not especially limited as long as it involves the above-mentioned heat treatment step.

According to another embodiment of the above-mentioned production method of the semiconductor device, the production method further includes: before the heat treatment step,

a first bonding step;

a semiconductor substrate-separating step; and

an element-dividing step, in this order,

wherein in the first bonding step,

a semiconductor substrate is bonded to the intermediate substrate,

the semiconductor substrate including: the at least part of each one of single-crystal semiconductor elements; and a cleavage layer including an implanted cleavage substance containing at least one of hydrogen ion and rare gas ion;

in the semiconductor substrate-separating step,

the semiconductor substrate is separated by cleavage of the cleavage layer by a heat treatment;

in the element-dividing step,

a remaining portion of the semiconductor substrate bonded to the intermediate substrate is thinned to give the single-crystal semiconductor thin film, and the semiconductor elements are divided; and

in the heat treatment step,

the single-crystal semiconductor thin film and the intermediate substrate undergo the heat treatment.

Thus, while the advantages of the present invention can be sufficiently exhibited, the semiconductor device including the thinned single-crystal semiconductor thin film-including single-crystal semiconductor elements can be more easily produced.

According to another embodiment of the above-mentioned production method of the semiconductor device, the production method further includes:

a first flattening step;

a cleavage layer-forming step;

a first bonding step;

a semiconductor substrate-separating step;

an element-dividing step;

a second flattening step; and

a second bonding step, in this order,

wherein in the first flattening step,

a first flattening layer is formed on a semiconductor elements side-surface of a semiconductor substrate including the at least part of each one of the semiconductor elements;

in the cleavage layer-forming step,

a cleavage layer is formed by implanting a cleavage substance containing at least one of hydrogen ion and rare gas ion into the semiconductor substrate at a predetermined depth through the first flattening layer;

in the first bonding step,

the first flattening layer is bonded to the intermediate substrate;

in the semiconductor substrate-separating step,

the semiconductor substrate is separated by cleavage of the cleavage layer by a heat treatment;

in the element-dividing step,

a remaining portion of the semiconductor substrate bonded to the intermediate substrate is thinned to give the single-crystal semiconductor thin film, and the semiconductor elements are divided;

in the second flattening film,

a second flattening layer is formed on a surface opposite to an intermediate substrate side-surface of the single-crystal semiconductor thin film; and

in the second bonding step,

the second flattening layer is bonded to the insulating substrate, and

wherein the heat treatment step is performed between the element-dividing step and the second flattening step or after the second flattening step, and

in the heat treatment step,

the single-crystal semiconductor thin film and the intermediate substrate undergo the heat treatment.

Thus, while the advantages of the present invention can be sufficiently exhibited, the semiconductor device including the thinned single-crystal semiconductor thin film-including single-crystal semiconductor elements can be more easily produced.

According to another embodiment of the above-mentioned production method of the single-crystal semiconductor thin film-including substrate, the production method further includes: before the heat treatment step,

a first bonding step;

a semiconductor substrate-separating step; and

a thinning step, in this order,

wherein in the first bonding step,

a semiconductor substrate including a cleavage layer including an implanted cleavage substance containing at least one of hydrogen ion and rare gas ion is bonded to the intermediate substrate;

in the semiconductor substrate-separating step,

the semiconductor substrate is separated by cleavage of the cleavage layer by a heat treatment; and

in the thinning step,

a remaining portion of the semiconductor substrate bonded to the intermediate substrate is thinned to give the single-crystal semiconductor thin film, and

wherein in the heat treatment step,

the single-crystal semiconductor thin film and the intermediate substrate undergo the heat treatment.

Thus, while the advantages of the present invention can be sufficiently exhibited, the thinned single-crystal semiconductor thin film can be more easily produced.

According to another embodiment of the above-mentioned production method of the single-crystal semiconductor thin film-including substrate, the production method further includes:

a cleavage layer-forming step;

a first bonding step;

a semiconductor substrate-separating step;

a thinning step;

a flattening step; and

a second bonding step, in this order,

wherein in the cleavage layer-forming step,

a cleavage layer is formed by implanting a cleavage substance containing at least one of hydrogen ion and rare gas ion into a semiconductor substrate at a predetermined depth;

in the first bonding step,

the semiconductor substrate is bonded to the intermediate substrate;

in the semiconductor substrate-separating step,

the semiconductor substrate is separated by cleavage of the cleavage layer by a heat treatment;

in the thinning step,

a remaining portion of the semiconductor substrate bonded to the intermediate substrate is thinned to give the single-crystal semiconductor thin film;

in the flattening step,

a surface opposite to the intermediate substrate side-surface of the single-crystal semiconductor thin film is flattened; and

in the second bonding step,

the flattening layer is bonded to the insulating substrate, and

wherein the heat treatment step is performed between the thinning step and the flattening step or after the flattening step, and

in the heat treatment step,

the single-crystal semiconductor thin film and the intermediate substrate undergo the heat treatment.

Thus, while the advantages of the present invention can be sufficiently exhibited, the single-crystal semiconductor thin film-including substrate, which includes the thinned single-crystal semiconductor thin film on the insulating substrate, can be more easily produced.

The intermediate substrate may include a separation layer formed therein at a predetermined depth. According to this, the intermediate substrate can be more easily removed after the single-crystal semiconductor elements or the single-crystal semiconductor thin film is bonded to the insulating substrate, which is a final substrate.

From this viewpoint, the production method of the semiconductor substrate may further include an intermediate substrate-separating step of separating the intermediate substrate by cleavage of the separation layer. The production method of the single-crystal semiconductor thin film-including substrate may further include an intermediate substrate-separating step of separating the intermediate substrate by cleavage of the separation layer.

According to another embodiment of the production method of the semiconductor substrate and the production method of the single-crystal semiconductor thin film-including substrate, the intermediate substrate includes a bonding layer partially opened in a plurality of regions on a surface thereof, and the separation layer has a structure in which part of the intermediate substrate is etched through the openings of the bonding layer. According to this, the intermediate substrate can be still more easily removed after the single-crystal semiconductor elements or the single-crystal semiconductor thin film is bonded to the insulating substrate, which is a final substrate.

The separation layer preferably has a column structure including a plurality of columns.

The separation layer may be a germanium-silicon alloy layer. Also in this embodiment, the intermediate substrate can be still more easily removed after the single-crystal semiconductor elements or the single-crystal semiconductor thin film is bonded to the insulating substrate, which is a final substrate. Thus, the separation layer may be an alloy layer including germanium and silicon.

As mentioned above, the production method of the semiconductor device of the present invention can involve the first transfer onto the intermediate substrate (the first bonding step) and the second transfer onto the insulating substrate (final substrate) (the second bonding step). As a result, according to the semiconductor device produced by the production method of the present invention, the arrangement position of the respective components of each one of the single-crystal semiconductor elements on the insulating substrate is inverted to that in conventional semiconductor device produced by a production method involving only one transfer onto an insulating substrate.

Thus, the present invention also includes semiconductor device comprising single-crystal semiconductor thin film-including single-crystal semiconductor elements on an insulating substrate,

wherein the insulating substrate has a heat-resistant temperature of 600° C. or lower,

the single-crystal semiconductor elements are MOS transistors in which a first gate electrode self-aligning with a channel of the single-crystal semiconductor thin film and a side wall self-aligning with an LDD region (lightly doped drain) of the single-crystal semiconductor thin film; a gate insulating film; and the single-crystal semiconductor thin film are stacked, and

the first gate electrode and the side wall are arranged in a layer upper than the single-crystal semiconductor thin film (hereinafter, also referred to as a “first semiconductor device of the present invention”).

The configuration of the first semiconductor device of the present invention is not especially limited. The first semiconductor device may or may not include other components as long as it essentially includes the above-mentioned components.

In the present description, the phrase that a layer upper than X means that a layer further away from the insulating substrate than X.

In the present description, the heat-resistant temperature is intended to refer to a practical heat-resistant temperature in production of the semiconductor device or the single-crystal semiconductor thin film-including substrate. The heat-resistant temperature is preferably a practical heat-resistant temperature for deformation and/or accuracy of dimension, more preferably for deformation and accuracy of dimension. The heat-resistant temperature depends on processes and varies depending on magnification correction, alignment method, acceptable degree of alignment (design rule), etc., in photolithography. So the heat-resistant temperature is appropriately determined in accordance with desired process conditions. The practical heat-resistant temperature is empirically lower than a strain point about by 70° C. (acceptable) to 100° C. (practical). So it is preferably lower than the strain point by 70° C., and more preferably by 100° C.

According to the production method of the single-crystal semiconductor thin film-including substrate of the present invention, a single-crystal semiconductor thin film with a small surface roughness, more specifically, with an average surface roughness Ra of 5 nm or smaller can be formed on an insulating substrate.

Thus, the present invention is also a single-crystal semiconductor thin film-including substrate including an insulating substrate and a single-crystal semiconductor thin film formed on the insulating substrate, wherein the insulating substrate has a heat-resistant temperature of 600° C. or lower, and the single-crystal semiconductor thin film has an average surface roughness Ra of 5 nm or smaller (preferably, 2 nm).

The configuration of the single-crystal semiconductor thin film-including substrate of the present invention is not especially limited. The substrate may or may not include other components as long as it essentially includes the above-mentioned components.

Single-crystal semiconductor thin films of the present invention other than the single-crystal semiconductor thin film-including substrate of the present invention also may each have an average surface roughness Ra of 5 nm (preferably, 2 nm) or smaller.

The present invention is also a semiconductor device including single-crystal semiconductor elements produced using a single-crystal semiconductor thin film-including substrate produced by the production method of the single-crystal semiconductor thin film-including substrate of the present invention (hereinafter, also referred to as a “second semiconductor device of the present invention”).

The present invention is also a semiconductor device including single-crystal semiconductor elements produced using the single-crystal semiconductor thin film-including substrate of the present invention (hereinafter, also referred to as a “third semiconductor device of the present invention”).

The single-crystal semiconductor thin film-including substrate may be a SOI substrate.

The single-crystal semiconductor thin film-including single-crystal semiconductor elements are preferably single-crystal TFTs.

As mentioned above, according to the present invention, the inactivated acceptors (preferably, boron) in the single-crystal semiconductor thin film can be activated. As a result, an activation ratio of the acceptors in the single-crystal semiconductor thin film can be increased to 50% or larger. It is preferable that an activation ratio of acceptors in the single-crystal semiconductor thin film is 50% or larger (more preferably 70% or larger).

It is preferable that the insulating substrate has a strain point of 800° C. (more preferably 670° C.) or lower. According to this, a glass substrate, which is used in a panel for display devices, can be used as the insulating substrate. The present invention can be preferably applied to thin-profile display devices such as an LCD device and an organic EL display device. The strain point is a temperature where internal stress in glass and the like is substantially removed in four hours, and it is a temperature giving a viscosity of 4×10¹⁴ P (dyn/cm²) to the glass and the like in four hours.

From the same view point, it is preferable that the insulating substrate is a glass substrate. Particularly preferably, the insulating substrate is a glass substrate having a strain point of 800° C. or lower and a heat-resistant temperature of 600° C. or lower.

Specific examples of preferable materials for the insulating substrate include (1) aluminoborosilicate glass (2) aluminosilicate glass, (3) barium borosilicate glass, (4) glass mainly containing an oxide of aluminum (Al), boron (B), silicon (Si), calcium (Ca), magnesium (Mg), or barium (Ba).

The above-mentioned insulating substrate may be a metal substrate (preferably, stainless substrate) including an insulating layer (preferably, an inorganic insulating film such as a SiNₓ/SiO₂ multilayer film and a SiO₂ single film) formed thereon. The insulating substrate may be a resin substrate (plastic substrate), and an insulating layer (preferably, an inorganic insulating film such as a SiO₂ film) may be formed thereon. If the insulating substrate is a resin substrate, it is preferable that the single-crystal semiconductor elements are bonded to the insulating substrate with a resin adhesive therebetween, and it is also preferable that the single-crystal semiconductor thin film is bonded to the insulating substrate with a resin adhesive therebetween. The heat-resistant temperature of the resin substrate is preferably about 200° C. or lower.

According to the present invention, the transistor characteristics can be improved. More specifically, a subthreshold slope of the single-crystal semiconductor elements can be 75 mV/dec (preferably, 65 to 75 mV/dec) or smaller. The subthreshold slope of the single-crystal semiconductor elements is preferably 75 mV/dec (preferably 65 to 75 mV/dec) or smaller.

The semiconductor device may further include non-single-crystal semiconductor thin film-including non-single-crystal semiconductor elements on the insulating substrate. The single-crystal semiconductor thin film-including substrate may further include a non-single-crystal semiconductor thin film on the insulating substrate. According to this, the present invention can be preferably applied to thin-profile display devices such as a LCD device and an organic EL display device regardless of the size of the devices.

The non-single-crystal semiconductor thin film is preferably a polycrystal or amorphous semiconductor thin film.

The non-single-crystal semiconductor thin film-including non-single-crystal semiconductor elements are preferably non-single-crystal TFTs.

The single-crystal semiconductor elements may further include a second gate electrode formed on the insulating substrate side of the single-crystal semiconductor thin film. According to this embodiment, the threshold value of each one of the elements can be precisely controlled, and low voltage operation and a reduction in leakage current at an off-state are allowed while the performances are kept.

The single-crystal semiconductor elements may include a PMOS transistor and a NMOS transistor, and the second gate electrode may be independent between the PMOS transistor and the NMOS transistor. This allows accurate control of threshold values of the PMOS transistor and the NMOS transistor.

It is preferable that the second gate electrode does not self-align with the channel of the single-crystal semiconductor thin film. According to this embodiment, the second gate electrode can be easily formed after the heat treatment step.

The single-crystal semiconductor elements further include a wiring arranged on the insulating substrate side of the single-crystal semiconductor thin film, and the second gate electrode and the wiring are positioned in the same layer. This allows that the second gate electrode and the wiring can be formed in the same step, which leads to simplification of the production steps.

The second gate electrode may be connected to the first gate electrode. In this case, a threshold voltage (absolute value) at an on-state is decreased and that at an off-state is increased. This leads to an improvement in performances at low voltages, a decrease in leakage current at an off-state, and operation at lower supply voltages (without a reduction in performances).

A bonded interface between the insulating substrate and the single-crystal semiconductor elements preferably contains SiO₂—SiO₂ bond or SiO₂-glass bond. A bonded interface between the insulating substrate and the single-crystal semiconductor thin film preferably contains SiO₂—SiO₂ bond or SiO₂-glass bond. According to this, the insulating substrate can be more tightly bonded to the single-crystal semiconductor elements or the single-crystal semiconductor thin film.

The single-crystal semiconductor thin film is preferably a single-crystal Si thin film. Specifically, the single-crystal semiconductor thin film preferably contains Si. The single-crystal semiconductor thin film may contain strained silicon. Thus, the single-crystal semiconductor thin film may have a tensile stress or a compressive stress, so the single-crystal semiconductor elements with an extremely high mobility can be provided.

The single-crystal semiconductor elements may include a PMOS transistor, and the PMOS transistor may include a strained (100) silicon film and have a compressive stress. The PMOS transistor may include a strained (100) silicon film and have a tensile stress. The single-crystal semiconductor elements may include a NMOS transistor, and the NMOS transistor may have a tensile stress. According to these embodiments, the PMOS and NMOS transistors with an extremely high mobility can be provided.

The single-crystal semiconductor thin film may contain at least one semiconductor selected from the group consisting of germanium (Ge), silicon carbide (SiC), and gallium nitride (GaN). Use of Ge enables the single-crystal semiconductor element to have a higher mobility, compared with use of silicon. Use of SiC enables the single-crystal semiconductor element to have higher mobility, higher photosensitivity, and higher resistance to junction voltage compared with use of silicon. Use of GaN can increase the resistance to junction voltage compared with use of silicon, and as a result, losses attributed to an LDD region and the like can be suppressed.

It is preferable that the insulating substrate is larger than a region where the single-crystal semiconductor elements are arranged. It is preferable that the insulating substrate is larger than the single-crystal semiconductor thin film. According to these embodiments, the present invention can be preferably applied to thin-profile display devices such as an LCD device, and an organic EL display device. Thus the insulating substrate may be larger than the single-crystal semiconductor thin film before being transferred. The insulating substrate is preferably larger than the semiconductor substrate (semiconductor wafer).

From the same viewpoint, it is preferable that the single-crystal semiconductor thin film-including substrate includes a plurality of the single-crystal semiconductor thin films, and the single-crystal semiconductor thin films are closely arranged in an island pattern in a plane (more preferably in the entire plane) of the insulating substrate. The single-crystal semiconductor thin film-including substrate may include a plurality of the single-crystal semiconductor thin films, and single-crystal semiconductor thin films are closely arranged in an island pattern in a plane (more preferably in the entire plane) of the insulating substrate in a tile pattern. According to these embodiments, the plurality of the single-crystal semiconductor thin films is not necessarily evenly arranged in the insulating substrate plane. The thin films may be arranged with a space or without a space therebetween.

Thus, according to the single-crystal semiconductor thin film-including substrate, a plurality of the single-crystal semiconductor thin films may be arranged in an island pattern in a plane (more preferably, the entire plane) of the insulating substrate. Further, according to the single-crystal semiconductor thin film-including substrate, the thin films may be arranged in a plane (more preferably, the entire plane) of the insulating substrate in a tile pattern. Also according to these embodiments, the plurality of the single-crystal semiconductor thin films may not be necessarily evenly arranged in an island pattern in the insulating substrate plane (more preferably the entire plane). The thin films may be arranged with a space or without a space therebetween.

As mentioned above, according to the present invention, metal materials with a low melting point such as low-resistance aluminum (Al) alloys can be used as a material for wirings. It is preferable that the semiconductor device further includes a first wiring containing a low-resistance metal material on an insulating substrate side of the single-crystal semiconductor thin film. A range of a preferable sheet resistance of the first wiring may vary to some degree depending on conditions such as the thickness of the first wiring and design constraints, and more specifically it is within a range of about 0.05 to 0.2Ω/□.

When the semiconductor substrate includes the first wiring containing a low-resistance metal material on the insulating substrate side of the single-crystal semiconductor thin film, the semiconductor device may include a second wiring arranged in a layer upper than the single-crystal semiconductor thin film and in contact with at least part of the single-crystal semiconductor thin film, and the second wiring contains a metal material with a heat-resistant temperature of 650° C. or higher. As a result, the wirings can be stacked, leading to an increase in integration density.

Thus, the semiconductor device may include the first wiring and the second wiring, wherein the first wiring containing a low-resistance metal material on the insulating substrate side of the single-crystal semiconductor thin film, and the second wiring containing a metal material with a heat-resistant temperature of 650° C. or higher is arranged in a layer upper than the single-crystal semiconductor thin film and in contact with at least part of the thin film.

It is preferable that a variation in thickness of the single-crystal semiconductor thin film is 10% (more preferably 5%) or smaller. As a result, the transistor characteristics of the single-crystal semiconductor elements can be more improved.

As mentioned above, the present invention provides the thin film semiconductor elements (thin film device) or the semiconductor thin films, preferably produced by the following procedures in this order: cleavage substances such as hydrogen ions are implanted into a Si substrate or an element-on Si substrate at a predetermined depth; the substrate surface is flattened; the flat substrate surface is bonded to a high heat-resistant intermediate substrate including a separation structure (or separation layer); the hydrogen ion-implanted portion (cleavage zone) is cleaved to separate part of the Si substrate by a heat treatment; the entire surface of the transferred part undergoes etch-back or CMP until the thickness of the part is decreased to a predetermined value or until the semiconductor elements are divided; a SiO₂ film and the like is deposited on the Si thin film for flattening; before or after the flattening, the heat treatment at about 650° C. to 800° C. or higher is performed; low resistant wiring made of aluminum (Al), copper (Cu), and the like is formed; the intermediate substrate is bonded to the insulating substrate; and the intermediate substrate is separated from the separation structure (or the separation layer) by etching or stress.

The present invention permits a heat treatment at a temperature higher than a heat-resistant temperature of a glass substrate, which is impossible in conventional technologies, and so thermal donor influences, inactivation of boron, and the like, caused by hydrogen in Si film, can be suppressed. As a result, excellent device characteristics can be provided. Further, low-resistance wirings can be used, and the thickness of the single-crystal semiconductor thin film can be easily controlled, and a single-crystal semiconductor thin film excellent in surface flatness can be provided.

### EFFECT OF THE INVENTION

According to the semiconductor device, the single-crystal semiconductor thin film-including substrate, and production methods thereof of the present invention, an improvement in transistor characteristics and a reduction in wiring resistance are permitted in single-crystal semiconductor thin film-including single-crystal semiconductor elements transferred onto a low heat-resistant insulating substrate.

### BEST MODES FOR CARRYING OUT THE INVENTION

The present invention is mentioned in more detail with reference to drawings showing Embodiments but not limited to only these Embodiments.

### Embodiment 1

A single-crystal Si semiconductor device of Embodiment 1 and a production method thereof are mentioned below with reference to FIGS. 1-1 to 1-3 and FIGS. 2-1 to 2-3. FIGS. 1-1(a) to 1-1(d), FIGS. 1-2(e) and 1-2(f), and FIGS. 1-3(g) and 1-3(h) are cross-sectional views each schematically showing a production step of the semiconductor device of Embodiment 1. FIGS. 2-1 and 2-2 are schematic views each showing an intermediate substrate of Embodiment 1 in the production step. FIG. 2-1(a) is a plan view thereof. FIG. 2-1(b) is a cross-sectional view taken along line X1-X2 of FIG. 2-1(a). FIG. 2-2(a) is a plan view thereof. FIG. 2-2(b) is a cross-sectional view taken along line Y1-Y2 of FIG. 2-2(a). FIG. 2-3 is a schematic view showing a modified example of the intermediate substrate of Embodiment 1. FIG. 2-3(a) is a plan view thereof. FIG. 2-3(b) is a cross-sectional view taken along line Z1-Z2 of FIG. 2-2(a). In the plan views of FIGS. 2-1 to 2-3, the intermediate substrate has a rectangular shape for convenience in drawing, but may not necessarily have such a shape.

The semiconductor device of the present Embodiment includes at least MOS single-crystal Si TFTs disposed at part of a glass substrate used in active matrix display panels, larger than 6-inch, 8-inch, or 12-inch Si or quartz wafers, which are industrially used in LSI production, or disposed at part of a similar-sized insulating substrate, which has an insulating surface. According to a first application of the present invention, the semiconductor device is a high-performance and advanced semiconductor device that also includes non-single-crystal Si TFTs including amorphous silicon (a-Si) and/or polysilicon (Poly-Si) disposed at another region of the insulating substrate.

Referring to FIG. 1-3(h), a semiconductor device 100 of the present Embodiment includes, on an insulating substrate 101: MOS non-single-crystal Si TFTs 100b including a non-single-crystal Si thin film 101b made of polysilicon; MOS single-crystal Si TFTs (single-crystal Si thin film elements) 100a including a single-crystal Si thin film 101a; an interlayer flattening film 107 covering the TFTs 100a and 100b; and a metal wiring 104 connecting the TFTs 100a to 100b.

The insulating substrate 101 was a high strain-point glass, or Corning code 1737 glass (alkaline earth-aluminoborosilicate glass, strain point: 667° C., heat-resistant temperature: 560° C. to 600° C.). Heat-resistant temperatures are not uniquely determined, and depend on a process and vary depending on magnification correction, alignment method, acceptable degree of alignment (design rule), etc., in photolithography. For example, a Corning code 1737 glass (size: 730 nm×920 mm) in 3 micron line/space is commonly regarded to have a heat-resistant temperature of 560° C. to 600° C. Practical heat-resistant temperatures for deformation are evaluated based on whether or not an object can be vacuum-held by a stage of an exposure device or based on a difference in pattern position before and after heat history, for example. It is preferable that the insulating substrate 101 has a heat-resistant temperature not lower than a heat treatment temperature (preferably 550° C. to 600° C.) in a step of forming the non-single-crystal Si thin film 101b.

A flat oxide film (not shown) composed of a SiO₂ (silicon dioxide) film with about 50 nm in thickness may be formed over the entire surface on the TFTs 100a and 100b side of the insulating substrate 101. In this case, the oxide film may function as a base layer.

The TFTs 100b include the non-single-crystal Si thin film 101b, a gate insulating film 102b composed of a SiO₂ film, and a gate electrode 103b on an interlayer insulating film 108b composed of a SiO₂ film. Although the gate electrode 103b is made of TiN, it may be made of polysilicon, silicide, polycide, and the like. An interlayer insulating film 109b composed of a SiO₂ film with about 200 nm to 500 nm in thickness is formed to cover the TFTs 100b.

The TFTs 100a include: a gate electrode 103 self aligning with a channel 101a/C of the single-crystal Si thin film 101a; a contact 105a; flattening layers 110 and 111; a gate insulating film 102a composed of a SiO₂ film; the single-crystal Si thin film 101a having the channel 101a/C, an LDD region 101a/LDD, and a source-drain 101a/SD; a side wall 114 (also referred to as a spacer) self aligning with the LDD region 101a/LDD; and a metal wiring 104a connected to the source-drain 101a/SD and the contact 105a. Heavily-doped p-Si film was used as a material for the gate electrode 103a and the contact 105a. The contact 105a may be made of the single-crystal Si layer (the layer constituting the single-crystal Si thin film 101a). The gate electrode 103a and the side wall 114 are arranged in a layer upper than the single-crystal Si thin film 101a. The TFTs 100a are divided from one another by a LOCOS oxide film 106a. The film 106a may be STI (shallow trench isolation).

These single-crystal Si TFTs 100a are transferred onto the insulating substrate 101 after the following processes. A semiconductor portion of the TFTs 100a is first formed on a single-crystal Si substrate; the single-crystal Si substrate is bonded to an intermediate substrate including a separation layer; a high-temperature heat treatment is performed for the TFTs 100a; and then the intermediate substrate including the gate electrode 103a, the gate insulating film 102a, and the single-crystal Si thin film 101a is bonded to the insulating substrate 101. The formation of the gate electrode 103a, the contact 105a, the metal wiring 104a and the like of the TFTs 100a, and the impurity ion implantation into the source-drain 101a/SD and the like may be performed after the transfer onto the insulating substrate. However, by performing, before the transfer, the formation of the gate electrode 103a, the contact 105a, the metal wiring 104a and the like, the impurity ion implantations for the source-drain 101a/SD formation and the LDD region 101a/LDD formation, or further the impurity ion implantation for the HALO formation for reduction in short-channel effect, the single-crystal Si thin film can be finely processed more easily as compared with the case where these processes are performed after the transfer.

The transfer onto the intermediate substrate involves the hydrogen ion-implanting step and heat treatment for increasing bonding strength and/or the cleavage and thinning step.

According to the semiconductor device 100 of the present invention, as mentioned above, the MOS non-single-crystal Si TFTs 100b and the MOS single-crystal Si TFTs 100a are both arranged on one insulating substrate 101. The semiconductor device 100 can be a high performance and advanced semiconductor device where circuits different in characteristics are integrated.

Further, the production costs on the semiconductor device 100 can be lower than costs on production of a semiconductor device including only single-crystal Si TFTs on one insulating substrate 101.

These production steps have no such area constrains as arising when only single-crystal Si TFTs are disposed. Displays larger than large-size Si wafers can be produced without any substrate size constraints.

If, for example, the semiconductor device 100 is applied to an active matrix substrate used in an LCD device, the device 100 further includes a SiNₓ (silicon nitride) film, a resin flattening film, a via hole, a transparent electrode, and the like, for LC display. The non-single-crystal Si TFTs (non-single-crystal Si elements) 100b constitute TFTs in a driver portion and a display portion. The single-crystal Si device TFTs 100a, which can be used in device needing higher performances, constitute a timing controller, a memory, and the like. The driver portion may be also constituted by the TFTs 100a, which is determined by considering the costs and the performances. The function and application of the TFTs 100a and 100b are determined depending on their characteristics. As a result, high performance and advanced semiconductor device and display device can be provided.

In the semiconductor device 100, an integrated circuit is formed in the non-single-crystal Si thin film 101b region and in the single-crystal Si thin film 101a region. This allows integrated circuits including a pixel array to be formed in different regions in accordance with desired configuration and characteristics. Further, the integrated circuits formed in different regions can be different in performances, operation speed, power voltage, and the like. For example, the circuits may be so designed to be different in at least one of gate length, gate insulating film thickness, power source voltage, and logic level from one region to the other.

Thus, a semiconductor device or a display device that can show more various functions attributed to the elements having different characteristics from one region to the other can be provided.

In the semiconductor device 100, the IC is formed in both of the non-single-crystal Si thin film 101b region and the single-crystal thin film 101a region. The ICs can be formed with process rules in accordance with the respective regions. For example, in short channel length elements, no crystal grain boundary exists in the single-crystal Si thin film 101a region and so a variation in TFT characteristics is not so increased. In contrast, in the non-single-crystal Si thin film 101b region, the variation in the TFT characteristics is highly increased under the influence of the grain boundary. Thus, it is necessary to determine the process rule in accordance with the respective regions, i.e., the thin film 101a region and the thin film 101b region. According to the semiconductor device 100, the ICs with process rules suitable for their arrangement regions can be formed.

The size of the single-crystal Si device formed on the semiconductor device 100 is determined by a wafer size of an LSI production apparatus. A wafer size of a common LSI production apparatus is enough for a high-speed DAC (current buffer), which needs a high-speed performance, a power consumption, a high-speed logic, a timing generator, a variation, etc., or for a circuit such as a processor, each of which needs to include the thin film 101a.

The production method of the semiconductor device 100 is mentioned with reference to FIGS. 1-1 to 1-3 and FIGS. 2-1 and 2-2 below.

The production method of the device 100 is roughly mentioned below. A single-crystal Si substrate 500 including a portion that can give the single crystal Si TFTs 100a after thinning is prepared, and hydrogen ions at a predetermined concentration are previously implanted into the substrate 500 at a predetermined depth. This substrate 500 is bonded to the intermediate substrate 600 including a separation structure. Then, the substrate 500 is cleaved by cleavage of the hydrogen ion-implanted portion (cleavage layer) by a heat treatment. Then, the substrate 500 is thinned by etching or polishing to give the single crystal Si thin film 101a, and the elements are divided. Further, the interlayer insulating film 108a including a SiO₂ film and the like is formed by deposition to flatten a surface defined by the TFTs 100a. Before or after the flattening film 108a formation, the single-crystal Si thin film 100a on the intermediate substrate 600 undergoes annealing at a high temperature of 650° C. or higher, thereby curing the defects, reducing the thermal donors, or activating the inactivated boron. Then, contact formation, metal wiring 104a formation, and flattening film 111 formation involving deposition of SiO₂ film, are performed. Then, the intermediate substrate 600 is bonded to the insulating substrate 101 and separated from the separation structure. In this manner, the transfer is completed.

Specifically, some of CMOS processes were previously performed in a common IC production line. Specifically, performed were implantation of impurity ions (e.g., BF₂⁺) for the channel 101a/C formation, formation of the gate insulating film 102a and the LOCOS oxide film 106a, pattern formation of the gate electrode 103a and the contact 105a, implantation of impurity ions (e.g., P⁺) for the LDD region 101a/LDD formation, formation of the side wall 114, implantation of impurity ions (e.g., P⁺) for source-drain 101a/SD formation. After that, the SiO2 film was formed and then polished by CMP (chemical-mechanical polishing) to give the flattening film 110 (first flattening step).

As shown in FIG. 1-1(a), the cleavage substances, or hydrogen ions at 6×10¹⁶/cm² were implanted at a predetermined energy, and thereby a hydrogen ion-implanted portion (cleavage layer) 120 was formed in the single-crystal Si substrate 500 (cleavage layer-forming step).

Instead of the substrate 500, a single-crystal Ge substrate may be used as the single-crystal semiconductor substrate. Specifically, a single-crystal Ge thin film may be used instead of the single-crystal Si thin film 101a.

Referring to FIG. 1-1(b), this single-crystal Si substrate 500 and the intermediate substrate 600 including a previously-formed separation structure (separation layer) 605 were hydrophilized and then bonded to each other (a first bonding step). More specifically, the flattening film 100 of the substrate 500 was bonded to the thermal oxide film 602 of the intermediate substrate 600.

A substrate with a heat-resistant temperature of about 650° C. (more preferably, about 700° C., still more preferably about 800° C.) or higher is preferably used as the intermediate substrate 600. A Si wafer was used as the intermediate substrate 600. The intermediate substrate 600 was formed as follows.

Now referring to FIG. 2-1, a Si wafer 601 is thermally oxidized to give a thermal oxide film 602 with about 200 nm in thickness, which is to be a bonding layer to which the single-crystal Si substrate 500 is to be bonded. The thermal oxide film 602 is provided with openings 603 with about 0.5 μm in diameter by photolithography. The openings 602 are arranged with about 1.5 μm pitch. Then, as shown in FIG. 2-2, the Si wafer 601 is wet-etched with an alkali solution such as TMAH to form a Si columnar structure 604. As a result, the intermediate substrate 600 having the separation structure 605 can be prepared. The separation structure 605 has strength low enough to be separated (broken) by stress, preferably twist and/or slide stress. This allows the intermediate substrate 600 to be more easily separated later.

For the etching, gas capable of etching Si such as XeF may be used. When the Si columnar structure 604 has a proper size, the intermediate 600 can endure the CMP but can be separated by twist stress. The etching may be terminated before the column structure 604 is formed, and as shown in FIG. 2-3, a separation structure 605 in which adjacent ones of the openings 603 may be partitioned by a wall structure 606.

The intermediate substrate 600 may include a GeSi layer as the separation structure (separation layer) 605 of the intermediate substrate 600.

Then, annealing is performed at 300° C. for about 2 hours to increase the bonding strength. Then, the annealing temperature is increased to 580° C. As a result, part of the single-crystal Si substrate 500 is separated from the hydrogen ion-implanted portion 120, whereby the intermediate substrate 600 including an integrated circuit composed of the single-crystal Si thin film-including TFTs can be produced (semiconductor substrate-separating step).

The hydrogen ion-implanted portion 120-side surface of the single-crystal Si substrate 500 is thinned by polishing and/or etching to give the single-crystal Si thin film 101a. Thus, the element division has been completed (element-dividing step).

Then an interlayer insulating film 108a composed of a SiO₂ film is deposited on the single-crystal Si thin film 101a by plasma CVD (PECVD) using a gaseous mixture of TEOS (tetraethoxysilane) and O₂. Then the substrate shown in FIG. 1-1(c) is subjected to furnace annealing for about 30 minutes at about 650° C. or higher (preferably about 700° C. or higher, and more preferably about 750° C. or higher) (heat treatment step). In the present Embodiment, the furnace annealing was performed at about 800° C. Thus, the hydrogen atoms can be sufficiently removed from Si, and thermal donor and lattice defects in Si can be completely eliminated. Further, the acceptors can be reactivated. As a result, reproducibility of the transistor characteristics can be improved, and the transistor characteristics can be stabilized. The activation ratio of the acceptors in the single-crystal Si thin film 101a can be 50%, specifically 80% in the present Embodiment.

The heat treatment temperature is appropriately determined in accordance with the implanted hydrogen amount, the material of the intermediate substrate, and the like. When it is too high, a profile of the impurity (especially boron) is changed. So preferably, the heat treatment temperature is as low as possible within a range where the impurity profile is not changed, for example, at 850° C. (preferably, 820° C.) or lower. In order to reactivate the acceptors, it is preferable that the heat treatment temperature is as high as possible and is not lower than 650° C.

The activation ratio is estimated from a ratio of a density of active acceptors estimated based on a threshold voltage of a transistor to the total number of atoms or density of acceptors (borons in the present Embodiment) evaluated by SIMS (secondary ion mass spectrometer).

Referring to FIG. 1-1(d), formation of contact holes, metal layer deposition, and patterning are successively formed to give the metal wiring 104a. An Al—Cu (0.5%) alloy (sheet resistance: 50 to 200 mΩ/□, thickness: 150 to 600 nm) was used for the metal wiring 104a, and it may be other Al alloys such as an Al—Si alloy (sheet resistance: 230 mΩ/□, thickness: 200 nm) and an Al—Nd alloy (sheet resistance: 230 mΩ/□, thickness: 100 nm) or copper. The subsequent steps exclude high-treatment temperatures, and so the above-mentioned low-resistance metal materials can be used for the metal wiring 104a.

A SiO₂ film is further deposited to cover the metal wiring 104a in the single crystal Si substrate 500 using a gaseous mixture of TEOS and O₂ by PECVD. Then, this SiO₂ film is flattened by CMP to give the flattening film 111 (second flattening step).

Then the intermediate substrate 600 including the single-crystal Si TFTs 100a was divided into predetermined sizes, and as shown in FIG. 1-2(e), a high-strain point glass (e.g., the above-mentioned glass substrate), which is industrially used for TFT-LCDs, was used as the insulating substrate (final substrate) 101 having an insulating surface. Both of the intermediate substrate 600 and the insulating substrate 101 including the non-single-crystal Si TFTs 100b were activated (hydrophilized) by being impregnated in a solution containing hydrogen peroxide such as a SC-1 solution. Then, the substrate 500 was positioned with a predetermined region of the insulating substrate 101 and then tightly bonded to each other at room temperatures (second bonding step). More specifically, the flattening film 111 of the substrate 500 was bonded to the insulating substrate 101. When a glass substrate is used, its surface can be hydrophilized without depositing the SiO₂ film thereon. Some kinds of glasses satisfy an average surface roughness Ra of 0.2 to 0.3 nm or smaller, desired for excellent bonding property.

The intermediate substrate 600 and the insulating substrate 101 are bonded by Van der Waals forces and hydrogen bonding. A heat treatment at 400° C. to 600° C. (about 550° C. in the present Embodiment) is performed to cause a reaction of —Si—OH+—Si—OH→Si—O—Si+H₂O, and thereby the bond between the two substrates changes into a tight bond between the atoms. This heat temperature is preferably as low as possible as mentioned above particularly when the low-resistance metal material is used for the metal wiring 104a.

The single-crystal Si TFTs 100a are bonded to the insulating substrate 101 with the flattening film 111, which is an inorganic insulating film. Compared with use of a conventional adhesive, pollution of the single-crystal Si thin film 101a can be surely prevented.

Thus, it is preferable that the TFTs 100a and the insulating substrate 101 are finally bonded through SiO₂—SiO₂ bond (SiO₂ film and SiO₂ film bond) or SiO₂-glass bond (SiO₂ film and glass bond).

The insulating substrate 101 may be a metal substrate (for example, a stainless substrate) having a flattened surface defined by a SiNₓ—SiO₂ multilayer film, a SiO₂ single film, and the like formed thereon. As a result, the heat resistance and shock resistance of the insulating substrate 101 can be improved. This embodiment is particularly preferably applied to organic EL displays because the insulating substrate 101 may not have transparency when being used in organic EL displays.

The insulating substrate 101 may be a plastic substrate having a flat surface defined by a SiO₂ film formed thereon. Further, when a plastic substrate is used as the insulating substrate 101, the single-crystal Si TFTs 100a and the insulating substrate 101 may be bonded with an adhesive, although the pollution of the thin film 101a is still concerned.

After the sufficient bonding strength is obtained in the second bonding step, twist or slide stress is applied to the intermediate substrate 600 to separate part of the intermediate substrate 600 along the separation structure 605, as shown in FIG. 1-2(f) (intermediate substrate-separating step).

Now referring to FIG. 1-3(g), a remaining columnar Si portion on the single-crystal Si element and the thermal oxide film 602 are removed by etching, and then an internal flattening film composed of a SiO₂ film with about 300 nm in thickness is deposited using a gaseous mixture of SiH₄ and N₂O or a gaseous mixture of TEOS and O₂ by PECVD.

Then as shown in FIG. 1-3(h), formation of contact holes, deposition of a Al—Si layer, and patterning are successively performed. As a result, the metal wiring 104 containing an Al—Si alloy was formed in the contact holes and on the interlayer flattening film 107.

According to the production method of the semiconductor device 100 of the present Embodiment, the non-single-crystal Si thin film (p-Si thin film) 101b is formed, and then, the single-crystal Si TFTs 100a are formed as mentioned above. Specifically, the TFTs 100a are bonded to the insulating substrate 101 on which the thin film 101b has been formed. So the surface of the insulating substrate 101, to which the intermediate substrate 600 is bonded, preferably has flatness. A protective film (for example, a molybdenum (Mo) film) is formed on the substrate 101 surface, and the oxide film in the bonding region is removed by fluoric acid etc., and then, the protective film is removed by a commercially-available SLA etchant and the like. In this manner, bonding failure and the like can be prevented.

According to the present Embodiment, the single-crystal Si thin film 101a on the intermediate substrate 600 excellent in heat resistance can be subjected to the high-temperature heat treatment, which allows curing of defects, a reduction in thermal donors, and activation of inactivated borons in the thin film 101a. As a result, the characteristics of the single-crystal Si TFTs 100a can be improved. More specifically, a subthreshold slope of the single-crystal Si TFTs 100a can be 75 mV/dec or smaller. In the present Embodiment, it was 65 mV/dec to 70 mV/dec.

The step of forming the metal wiring 104a can be performed after the heat treatment is sufficiently performed for the single-crystal Si thin film 101a on the intermediate substrate excellent in heat resistance. Low-resistance metal materials can be used as a material for the metal wiring 104a.

The subthreshold slope (S value) can be measured with a semiconductor parameter analyzer (for example, product of Agilent, 4155C or 4156C) in the following manner. Using this analyzer, gate voltage-dependent drain current values are measured. In a semilog plot of the gate voltage-dependent drain current, a tangent to the curve in the subthreshold region is drawn.

The lower limit of the S value at room temperatures is theoretically about 60 mV/dec when CD=0. The S value increases by localization energy level and the like. The S value is approximately determined from the following formula.

S=(kT/q)ln 10(1+C_{d}/Cₒₓ)

where C_{OX} being a gate oxide film capacitance; and C_{d} being a depletion layer capacitance.

In SOI structures as in the present Embodiment, C_{d} is almost 0 and a S value at room temperatures is close to the ideal value, 60 mV/dec (in fact, about 65 mV/dec to 75 mV/dec). In bulk Si, the S value is about 80 mV/dec to 100 mV/dec due to C_{d}. If a threshold voltage is different from a current at an off-state by 8 digits, application of 0.5V to 0.6 V is sufficient when 0.65V to 0.8V needs to be applied. This permits operation at low voltages without performance deterioration.

FIG. 3 is a cross-sectional view schematically showing a modified example of the semiconductor device of Embodiment 1.

The single-crystal Si TFTs 100a may further includes a gate electrode 112a arranged on the insulating substrate 101 side of the single-crystal Si thin film 101a. The TFTs 100a may have a double-gate structure. This allows that threshold values of the TFTs 100a can be precisely controlled separately between the PMOS TFTs and the NMOS TFTs.

The gate electrode 112a is formed in the following manner, for example. After the element-dividing step, a gate insulating film 113a composed of a SiO₂ film is formed on the single-crystal Si thin film 101a, and a conductive film made of TiN, polysilicon, silicide, polycide, and the like is pattern-formed. Thus, the gate electrode 112a is a gate electrode not aligning with the channel 101a/C of the single-crystal Si thin film 101a. However, the gate electrode 112a can be formed before the transfer onto the insulating substrate 101, and so it can be arranged with so high alignment accuracy with an apparatus for LSI.

FIG. 6 is a cross-sectional view schematically showing a modified example of the semiconductor device of Embodiment 1. FIG. 7 is a schematic view showing a modified example of the semiconductor device of Embodiment 1. FIG. 7(a) is a cross-sectional view thereof. FIG. 7(b) is a plan view thereof. The gate electrode 112a may be constituted by the layer forming the metal wiring 104 as shown in FIG. 6 when there is a sufficient space for the gate electrode 112a. Thus, the gate electrode 112a can be formed in the same step of forming the metal wiring 104a, which leads to simplification of the production steps. The gate electrode 112a may be connected to the gate electrode 103a as shown in FIGS. 7(a) and 7(b). According to this, a threshold voltage (absolute value) at an on-state is decreased, and that at an off-state is increased. So performances of the TFTs 100a at low voltages are enhanced and a leakage current at an off-state is decreased, which enables the TFTs to be operated at a lower supply voltage (without performance deterioration). In this case, the gate electrode 112a and the gate electrode 103a are connected to each other through an island-shaped connection 115a composed of a high concentration impurity region of the single-crystal Si thin film 101a similarly to the source-drain 101a/SD.

FIG. 8 is a cross-sectional view schematically showing a modified example of the semiconductor device of Embodiment 1.

The single-crystal Si TFTs 100a may further include a high heat-resistant wiring 116 made of a high heat-resistant conductive material on the flattening film 110, in addition to the metal wiring 104a. According to this, the wirings in the TFT 100a portions can be formed into a multi-layer structure, which increases the integration density.

The high heat-resistant wiring 116 can be formed by successively performing formation of contact holes, metal layer deposition, and patterning for the upper face of the substrate 500 shown in FIG. 1-1(a) or the substrate 500 on which if necessarily, an insulating film such as SiO₂ film has been formed. High melting point metals with stable characteristics such as tantalum (Ta), molybdenum (Mo), and molybdenum tungsten (MoW) may be used for the high heat-resistance wiring 116. In the present Embodiment, the high heat-resistant wiring 116 is a multi-layer body composed of tungsten (W) and titanium nitride (TiN) barrier layer. In this case, the high heat-resistant wiring 116 is connected to the metal wiring 104a through an island-shaped connection 115b composed of a high concentration impurity region of the single-crystal Si thin film 101a similarly to the source-drain 101a/SD.

As mentioned above, the single-crystal Si TFTs 100a are each independently a PMOS transistor or an NMOS transistor. The gate electrode 112a is independent between the PMOS transistor and the NMOS transistor.

### Embodiment 2

A thin film semiconductor device including single-crystal strained Si of Embodiment 2 and a production method thereof are mentioned with reference to FIGS. 4-1 to 4-5. FIGS. 4-1(a) to 4-1(c), FIGS. 4-2(d) to 4-2(f), FIGS. 4-3(g) to 4-3(i), FIGS. 4-4(j) to 4-4(m), and FIGS. 4-5(n) to 4-5(p) are cross-sectional views each schematically showing a production step of the semiconductor device of Embodiment 2.

With reference to FIG. 4-1(a), a strained Si structure is mentioned first. A mixed crystal of GeₓSi₁₋ₓ graded material is epitaxially grown (epi-growth) on a Si wafer (single-crystal Si substrate) 500 to form a graded layer (SiGe layer) 231 with 1 μm in thickness, and thereon, a GeₓSi₁₋ₓ (SiGe mixed crystal) is grown to have a thickness of about 1 μm as a buffer layer (buffer GeSi layer) 232. As a result, dislocation-free GeₓSi₁₋ₓ is grown. Further, thereon a Si layer with a thickness of about 10 nm to 20 nm is epitaxially grown, thereby growing a stained Si layer 201a, which is a single-crystal strained Si thin film having a tensile stress due to a difference in lattice constant. Thereon a SiO₂ film 212 with a thickness of about 50 to 100 nm is grown by LPCVD and the like, and if necessarily, a SiO₂ film, which finally has a thickness equivalent to that of the SiO₂ film 212, is formed.

Thus, the strained Si substrate 502 having a tensile or compressive stress is formed. Thus an NMOS transistor having a (100) face having a tensile stress shows a mobility about two times higher than that of an NMOS transistor including single-crystal Si at x=about 0.3. Similarly, a PMOS transistor having a (110) face having a tensile stress or a PMOS transistor having a (100) face having a compressive stress shows a mobility about two times higher than that of a PMOS transistor including single-crystal Si.

Instead of the strained Si substrate 502 including the strained Si layer 201a formed by epitaxial growth, a substrate including epitaxially grown SiC or GaN may be used.

As shown in FIG. 4-1(b), cleavage substances, or hydrogen ions are implanted so that the peak of the hydrogen ions is positioned in a predetermined region (the graded layer 231 in the present Embodiment) of the graded layer 231 and the buffer layer 232, whereby the hydrogen ion-implanted portion (cleavage layer) 220 is formed (cleavage layer-forming step). The cleavage substances may be rare gas ion, in addition to H ion and H₂ ion. Further, H ion may be used in combination with rare gas ion.

Then as shown in FIGS. 4-1(c) and 4-2(d), surfaces of both of this strained substrate 502 and the intermediate substrate 600 including the separation structure 605 and the thermal oxide film (bonding layer) 602 are activated (hydrophilized) by being impregnated in a solution containing hydrogen peroxide such as a SC-1 solution, as performed in Embodiment 1. Then, the two substrates 502 and 600 are tightly bonded to each other (first bonding step). More specifically, the SiO₂ film 212 of the strained Si substrate 502 is bonded to the thermal oxide film 602 of the intermediate substrate 600. The strained Si substrate 502 and the intermediate substrate 600 are bonded by Van der Waals forces and hydrogen bonding. The bonding strength is increased by annealing at 300° C. for about 2 hours. Then, the annealing temperature is increased to 580° C. As a result, as shown in FIG. 4-2(e), part of the single-crystal Si substrate 502 is separated from the hydrogen ion-implanted portion 220 by cleavage. Thus, the intermediate substrate 600 including the strained Si layer 201a can be provided (semiconductor substrate-separating step).

Then, the graded layer 231 and the buffer layer 232 on the strained Si layer 201a are removed by etching with an alkaline solution such as TMAH. As a result, the intermediate substrate 600 including the strained Si layer 201a, which is the single-crystal strained Si thin film (single-crystal semiconductor thin film), formed thereon, can be provided (thinning step).

This substrate 600 undergoes annealing at about 650° C. or higher (preferably, about 700° C. or higher, more preferably, about 750° C.), for example, at 700° C. to 800° C. for about 30 minutes, thereby reducing the hydrogen concentration and curing defects slightly generated by the hydrogen ion implantation (thermal treatment step). Thus, the hydrogen atoms can be sufficiently removed from Si, and thermal donors, lattice defects, and the like can be completely eliminated. Further, the acceptors can be reactivated. As a result, reproducibility of the transistor characteristics can be improved and the transistor characteristics can be stabilized.

The heat treatment temperature is appropriately determined in accordance with the implanted hydrogen amount, the material for the intermediate substrate, and the like. When it is too high, the strained Si layer 201a is relaxed, leading to a reduction in the effects of the strained Si layer or a change of impurity (especially boron) profile. So preferably, the heat treatment temperature is as low as possible within a range where the strained Si layer 201a is not relaxed or the impurity profile is not changed, for example, at 850° C. (preferably, 820° C.) or lower. In order to reactivate the acceptors, it is preferable that the heat treatment temperature is as high as possible and is not lower than 650° C.

Now referring to FIG. 4-2(f), a SiO₂ film is deposited on the strained Si layer 201a using a gaseous mixture of TEOS and O₂ by PECVD. Then, this SiO₂ film is flattened by CMP to give the flattening film 210 (flattening step).

The intermediate substrate 600 including the strained Si layer 201a is divided into predetermined sizes, and as shown in FIG. 4-3(g), a high-strain point glass (e.g., the glass substrate used in Embodiment 1), which is industrially used for TFT-LCDs, is used as an insulating substrate (final substrate) 201 having an insulating surface. Both of the substrates 600 and 201 are activated (hydrophilized). Then, the substrate 600 is positioned with a predetermined region of the insulating substrate 201 and then tightly bonded to each other at room temperatures (second bonding step). More specifically, the flattening film 210 of the strained Si substrate 502 is bonded to the insulating substrate 201. When a glass substrate is used, its surface can be hydrophilized without depositing the SiO₂ film thereon. Some kinds of glasses satisfy an average surface roughness Ra of 0.2 nm to 0.3 nm or smaller, desired for excellent bonding property.

The intermediate substrate 600 and the insulating substrate 201 are bonded by Van der Waals forces and hydrogen bonding. The bonding strength is increased by a heat treatment at 200° C. to 300° C. for about two hours, and then, as shown in FIG. 4-3(h), an interlayer insulating film 208 composed of a SiO₂ film and an a-Si film 233 are successively deposited by PECVD. The a-Si film 233 undergoes dehydrogenation annealing at 550° C. to reduce the hydrogen atoms contained therein and then is irradiated with XeCl eximer laser and the like to be crystallized, and as a result, a Poly-Si film 234 is formed. The dehydrogenation annealing at about 550° C. causes a reaction of —Si—OH+—Si—OH→Si—O—Si+H₂O, and thereby the bond between the two substrates changes into a tight bond between the atoms.

Thus, it is preferable that the strained Si layer 201a and the insulating substrate 201 are finally bonded to each other through SiO₂—SiO₂ bond (SiO₂ film-SiO₂ film bond) or SiO₂-glass bond (SiO₂ film-glass bond).

The insulating substrate 201 may be a metal substrate (for example, a stainless substrate) having a flattened surface defined by a SiNₓ—SiO₂ multilayer film, a SiO₂ single film, and the like formed thereon. As a result, the heat resistance and shock resistance of the insulating substrate 201 can be improved. This embodiment is preferably applied to organic EL displays because the insulating substrate 201 may not have transparency when being used in organic EL displays.

The insulating substrate 201 may be a plastic substrate having a flat surface defined by a SiO₂ film formed thereon. Further, when a plastic substrate is used as the insulating substrate 201, the single-crystal Si TFTs 200a (the intermediate substrate 600 including the strained Si layer 201a) and the insulating substrate 201 may be bonded with an adhesive therebetween although the pollution of the strained Si layer 201a is still concerned.

Then twist or slid stress is applied to the intermediate substrate 600 to separate part thereof along the separation structure 605 as shown in FIG. 4-3(i) (intermediate substrate-separating step).

Referring to FIG. 4-4(j), part of the columnar Si, which is a remaining portion of the separation structure 605 on the strained Si layer 201a, is removed by etching, and then the SiO₂ film 212 and the thermal oxide film (bonding layer) 602 are removed by etching, as shown in FIG. 4-4(k).

The thus-produced SOI substrate has a surface defined by a surface (surface on the side opposite to the buffer layers 231 and 232) more excellent in flatness of the strained Si layer 201a. More specifically, the average surface roughness Ra of the strained Si layer 201a can be 5 nm or smaller.

In the present description, the average surface roughness Ra is an arithmetic mean height (Ra) and measured with an atomic force microscopy (AMF) in accordance with JIS B 0601. For example, the substrate surface in 5 μm×5 μm is measured.

Further, a variation in thickness of the strained Si layer 201a is 10% (more preferably 5%) or smaller.

In the present description, the variation in thickness of the single-crystal semiconductor thin film is determined by observing a cross-section of the thin film with TEM or measuring a reflectance by optical interferometry (for example, using Nano Spec 6500A, product of Toho Technology, Corp.).

The Poly-Si film 234 and the strained Si layer 201a are etched into an island pattern, as shown in FIG. 4-4(k). Then, a gate insulating film (gate oxide film) 202 composed of a SiO₂ film is deposited as shown in FIG. 4-4(l), and a gate electrode 203 is pattern-formed as shown in FIG. 4-4(m).

Then, an impurity ion-implanting step (involving implantation of phosphorus and boron ions, FIG. 4-5(n)), an impurity ion-activating step, an interlayer insulating film 209-forming step (FIG. 4-5(o)), and a step of forming contact holes and a metal wiring 204 (FIG. 4-5(p)) are each performed in a manner common in poly-Si TFT-forming processes. The strained Si layer 201a-including single-crystal Si TFTs 200a and the poly-Si film 234-including non-single crystal Si TFTs 200b can be formed.

According to the present Embodiment, the stained Si layer 201a on the intermediate substrate 600 excellent in heat resistance can be subjected to the high-temperature heat treatment. So the curing of the defects, the reduction in thermal donors, and the activation of the inactivated borons in the strained Si layer 201a, are allowed. As a result, the characteristics of the strained Si layer 201a-including single-crystal Si TFTs 200a can be improved.

Further, the first transfer onto the intermediate substrate 600 is performed, and then the second transfer onto the insulating substrate 201, which is a final substrate, can be performed. So the strained Si layer 201a surface with insufficient flatness on the side where the cleavage layer 220 and the buffer layers 231 and 232 are arranged is positioned on the insulating substrate 201 side. The surface more excellent in flatness, defined by the strained Si layer 201a, can be positioned on the side opposite to the insulating substrate 201. Specifically, the strained Si layer 201a with so flat surface can be formed on the insulating substrate 201. As a result, the characteristics of the strained Si layer 201a-including single-crystal Si TFTs 200a can be more improved.

The strained Si layer 201a on the intermediate substrate 600 excellent in heat resistance is sufficiently heat-treated, and then the metal wiring 204-forming step can be performed. Low-resistance metal materials (for example, Al alloys or Cu) can be used as a material for the metal wiring 204.

The strained Si layer 201a may have the element structure or part thereof before being bonded to the intermediate substrate 600. In this case, the element structure or part thereof is formed in the layer 201a in the manner mentioned in Embodiment 1.

### Embodiment 3

A thin film semiconductor device including single-crystal Si of Embodiment 3 and a production method thereof are mentioned with reference to FIGS. 5-1 to 5-5 below. FIGS. 5-1(a) and 5-1(b), FIGS. 5-2(c) to 5-2(e) FIGS. 5-3(f) to 5-3(h), FIGS. 5-4(i) to 5-4(l), and FIGS. 5-5(m) to 5-5(o) are cross-sectional views schematically showing the semiconductor device of Embodiment 3.

A thermal oxide film 311 with a thickness of 50 nm is formed on a Si wafer (single-crystal Si substrate) 500 surface, first.

As shown in FIG. 5-1(a), cleavage substances, or hydrogen ions are implanted into the single-crystal Si layer so that the peak of the hydrogen ions is positioned at a predetermined depth, whereby a hydrogen ion-implanted portion (cleavage layer) 320 is formed (cleavage layer-forming step). The cleavage substances may be rare gas ion, in addition to H ion and H₂ ion. Further, H₂ ion may be used in combination with rare gas ion.

Referring to FIGS. 5-1(b) and 5-2(c), this Si wafer 500 and the intermediate substrate 600 including the separation structure 605 and the thermal oxide film (bonding layer) 602 are activated (hydrophilized) by being impregnated in a solution containing hydrogen peroxide such as a SC-1 solution, and then tightly bonded to each other at room temperatures (first bonding step). More specifically, the thermal oxide film 311 of the single-crystal Si substrate 500 is bonded to the thermal oxide film 602 of the intermediate substrate 600. The single-crystal Si substrate 500 and the intermediate substrate 600 are bonded by Van der Waals forces and hydrogen bonding. The bonding strength is increased by annealing at 300° C. for about two hours, and the temperature is increased to 580° C. According to this, as shown in FIG. 5-2(d), the single-crystal Si substrate 500 is separated from the hydrogen ion-implanted portion 320 by cleavage, and thus, the intermediate substrate 600 including the single-crystal Si layer 335 can be provided (semiconductor substrate-separating step).

The single-crystal Si layer 335 is etched or chem-mech polished. As a result, the intermediate substrate including the single-crystal Si thin film 301a with a predetermined thickness formed thereon can be provided (thinning step).

This substrate 600 undergoes annealing at about 650° C. or higher (preferably, about 700° C. or higher, more preferably, about 750° C.), for example, at 700° C. to 800° C. for about 30 minutes, thereby reducing the hydrogen concentration and curing defects slightly generated by the hydrogen ion implantation (thermal treatment step). Thus, the hydrogen atoms can be sufficiently removed from Si, and thermal donors, lattice defects, and the like can be completely eliminated. Further, the acceptors can be reactivated. As a result, reproducibility of the transistor characteristics can be improved and the transistor characteristics can be stabilized.

The heat treatment temperature is appropriately determined in accordance with the implanted hydrogen amount, the material for the intermediate substrate, and the like. When it is too high, a profile of the impurity (especially boron) is changed. So preferably, the heat temperature is as low as possible within a range where the impurity profile is not changed, for example, at 850° C. (preferably, 820° C.) or lower. In order to reactivate the acceptors, it is preferable that the heat temperature is as high as possible and is not lower than 650° C.

Then as shown in FIG. 5-2(e), a SiO₂ film is deposited on the single-crystal Si thin film 301a using a gaseous mixture of TEOS and O₂ by PECVD, and then flattened by CMP to give the flattening film 310 (flattening step). The flattening film 310 may be a thermal oxide film obtained from the single-crystal Si thin film 301a or an oxide film obtained by LPCVD. When the initial single-crystal Si thin film 301a has a sufficient flat surface and a thermal oxide film is formed, flattening after the oxidization, i.e., flattening for the thermal oxide film may or may not be performed.

The intermediate substrate 600 including the single-crystal Si thin film 301a is divided into predetermined sizes, and as shown in FIG. 5-3(f), a high-strain point glass (e.g., the glass substrate in Embodiment 1), which is industrially used for TFT-LCDs, is used as an insulating substrate (final substrate) 301 having an insulating surface. Both of the intermediate substrate 600 and the insulating substrate (final substrate) 301 are activated (hydrophilized). Then, the substrate 600 is positioned with a predetermined region of the insulating substrate 301 and then tightly bonded to each other at room temperatures (second bonding step). More specifically, the flattening film 310 of the single-crystal Si substrate 500 is bonded to the insulating substrate 301. When a glass substrate is used, its surface can be hydrophilized without depositing the SiO₂ film thereon. Some kinds of glasses satisfy an average surface roughness Ra of 0.2 to 0.3 nm or smaller, desired for excellent bonding property.

The intermediate substrate 600 including the single-crystal Si thin film 301a and the insulating substrate 301 are bonded by Van der Waals forces and hydrogen bonding. The bonding strength is increased by a heat treatment at 200° C. to 300° C. for about two hours, and then, as shown in FIG. 5-3(h), an interlayer insulating film 308 composed of a SiO₂ film and an a-Si film 333 are successively deposited by PECVD. The a-Si film 333 undergoes dehydrogenation annealing at 550° C. to reduce the hydrogen atoms contained therein and then is irradiated with XeCl eximer laser and the like to be crystallized, and as a result, a Poly-Si film 334 is formed. The dehydrogenation annealing at about 550° C. causes a reaction of —Si—OH+—Si—OH→Si—O—Si+H₂O, and thereby the bond between the two substrates changes into a tight bond between the atoms.

Thus, it is preferable that the single-crystal Si thin film 301a (the layer obtained by thinning the single-crystal Si layer 335) and the insulating substrate 301 are finally bonded to each other through SiO₂—SiO₂ bond (SiO₂ film-SiO₂ film bond) or SiO₂-glass bond (SiO₂ film-glass bond).

The insulating substrate 301 may be a metal substrate (for example, a stainless substrate) having a flattened surface defined by a SiNₓ—SiO₂ multilayer film, a SiO₂ single film, and the like formed thereon. As a result, the heat resistance and shock resistance of the insulating substrate 301 can be improved. This embodiment is preferably applied to organic EL displays because the insulating substrate 301 may not have transparency when being used in organic EL displays.

The insulating substrate 301 may be a plastic substrate having a flat surface defined by a SiO₂ film formed thereon. Further, when a plastic substrate is used as the insulating substrate 301, the single-crystal Si TFTs 300a (the single crystal Si substrate 500) and the insulating substrate 301 may be bonded with an adhesive therebetween, although the pollution of the single-crystal Si thin film 301a is still concerned.

Then twist or slide stress is applied to the intermediate substrate 600 to separate part thereof along the separation structure 605, as shown in FIG. 5-3(h) (intermediate substrate-separating step).

Now referring to FIG. 5-4(i), part of the columnar Si, which is a remaining portion of the separation structure 605 on the single crystal Si thin film 301a, is removed by etching, and then the SiO₂ film 312 and the thermal oxide film (bonding layer) 602 are removed by etching, as shown in FIG. 5-4(j).

The thus-produced SOI substrate has a surface defined by a surface (surface on the side opposite to the impurity ion-implanted portion 320) more excellent in flatness of the single-crystal Si thin film 301a. More specifically, the average surface roughness Ra of the single-crystal Si thin film 301a can be 5 nm or smaller.

Further, a variation in thickness of the single-crystal Si thin film 301a is 10% (more preferably 5%) or smaller.

Referring to FIG. 5-4(j), the Poly-Si film 334 and the single-crystal Si thin film 301a are etched into an island pattern. Then, a gate insulating film (gate oxide film) 302 composed of a SiO₂ film is deposited, as shown in FIG. 5-4(k), and a gate electrode 303 is pattern-formed as shown in FIG. 5-4(l)

Then, an impurity ion (phosphorus and boron)-implanting step (FIG. 5-5(m)), an impurity ion-activating step, an interlayer insulating film 309-forming step (FIG. 5-5(n)), and a step of forming contact holes and a metal wiring 304 (FIG. 5-5(o)) are each performed in a manner common in poly-Si TFT-forming processes. The single-crystal Si thin film 301a-including single-crystal Si TFTs 300a and the poly-Si film 334-including non-single crystal Si TFTs 300b can be formed.

According to the present Embodiment, the single-crystal Si thin film 301a on the intermediate substrate 600 excellent in heat resistance can be subjected to the high-temperature heat treatment. So the curing of the defects, the reduction in thermal donors, and the activation of the inactivated borons in the single-crystal Si thin film 301a, are allowed. As a result, the characteristics of the single-crystal Si thin film 301a-including single-crystal Si TFTs 300a can be improved.

Further, the first transfer onto the intermediate substrate 600 is performed, and then the second transfer onto the insulating substrate 301, which is a final substrate, can be performed. So the single-crystal Si thin film 301a surface with insufficient flatness on the side where the cleavage layer 320 is arranged is positioned on the insulating substrate 301 side. The surface more excellent in flatness, defined by the single-crystal Si thin film 301a, can be positioned on the side opposite to the insulating substrate 301. Specifically, the single-crystal Si thin film 301a with so flat surface can be formed on the insulating substrate 301. As a result, the characteristics of the single-crystal Si thin film 301a-including single-crystal Si TFTs 300a can be more improved.

The single-crystal Si thin film 301a on the intermediate substrate 600 excellent in heat resistance is sufficiently heat-treated, and then the metal wiring 304-forming step can be performed. Low-resistance metal materials (for example, Al alloys or Cu) can be used as a material for the metal wiring 304.

FIGS. 9(a) to 9(c), and FIG. 10 are schematic plan views each showing a modified example of Embodiments 2 and 3.

Embodiments 2 and 3 are not especially limited to the embodiment in which Si chips are transferred onto portions of an insulating substrate, which is a final substrate. For example, Si wafers 500 (the intermediate substrates 600) having a circular shape as viewed in plane are shaped into a substantially rectangular shape as viewed in plane (FIGS. 9(a) and 9(b), and then, the Si wafers 500 (the intermediate substrates 600) may be closely arranged on a large glass substrate 701 in such a manner as shown in FIG. 9(c). As a result, the variation in display characteristics of the display device can be suppressed, and particularly in current-driving devices such as organic EL displays, display uniformity can be markedly improved. The Si wafers 500 (the intermediate substrates 600) may be arranged without a space as shown in FIG. 9(c) or with a space as shown in FIG. 10.

The present application claims priority to Patent Application No. 2007-337922 filed in Japan on Dec. 27, 2007 under the Paris Convention and provisions of national law in a designated State, the entire contents of which are hereby incorporated by reference.

### BRIEF DESCRIPTION OF DRAWINGS

FIGS. 1-1(a) to 1-1(d) are cross-sectional views each schematically showing a production step of the semiconductor device of Embodiment 1.

FIGS. 1-2(e) and 1-2(f) are cross-sectional views each schematically showing a production step of the semiconductor device of Embodiment 1.

FIGS. 1-3(g) and 1-3(h) are cross-sectional views each schematically showing a production step of the semiconductor device of Embodiment 1.

FIG. 2-1(a) is a plan view schematically showing the intermediate substrate in the production step of Embodiment 1.

FIG. 2-1(b) is a cross-sectional view taken along line X1-X2 of FIG. 2-1(a).

FIG. 2-2(a) is a plan view schematically showing the intermediate substrate in the production step of Embodiment 1.

FIG. 2-2(b) is a cross-sectional view taken along line Y1-Y2 of FIG. 2-2(a).

FIG. 2-3(a) is a plan view schematically showing a modified example of the intermediate substrate of Embodiment 1.

FIG. 2-3(b) is a cross-sectional view taken along line Z1-Z2 in FIG. 2-3(a).

FIG. 3 is a cross-sectional view schematically showing a modified example of the semiconductor device of Embodiment 1.

FIGS. 4-1(a) to 4-1(c) are cross-sectional views each schematically showing a production step of the semiconductor device of Embodiment 2.

FIGS. 4-2(d) to 4-2(f) are cross-sectional views each schematically showing a production step of the semiconductor device of Embodiment 2.

FIGS. 4-3(g) to 4-3(i) are cross-sectional views each schematically showing a production step of the semiconductor device of Embodiment 2.

FIGS. 4-4(j) to 4-4(m) are cross-sectional views each schematically showing a production step of the semiconductor device of Embodiment 2.

FIGS. 4-5(n) to 4-5(p) are cross-sectional views each schematically showing a production step of the semiconductor device of Embodiment 2.

FIGS. 5-1(a) and 5-1(b) are cross-sectional views schematically showing a production step of the semiconductor device of Embodiment 3.

FIGS. 5-2(c) and 5-2(e) are cross-sectional views schematically showing a production step of the semiconductor device of Embodiment 3.

FIGS. 5-3(f) and 5-3(h) are cross-sectional views schematically showing a production step of the semiconductor device of Embodiment 3.

FIGS. 5-4(i) to 5-4(l) are cross-sectional views schematically showing a production step of the semiconductor device of Embodiment 3.

FIGS. 5-5(m) to 5-5(o) are cross-sectional views schematically showing a production step of the semiconductor device of Embodiment 3.

FIG. 6 is a cross-sectional view schematically showing a modified example of the semiconductor device of Embodiment 1.

FIG. 7(a) is a cross-sectional view schematically showing a modified example of the semiconductor device of Embodiment 1.

FIG. 7(b) is a plan view thereof.

FIG. 8 is a cross-sectional view schematically showing a modified example of the semiconductor device of Embodiment 1.

FIGS. 9(a) to 9(c) are plan views schematically showing a modified example of Embodiments 2 and 3.

FIG. 10 is a plan view schematically showing a modified example of Embodiments 2 and 3.

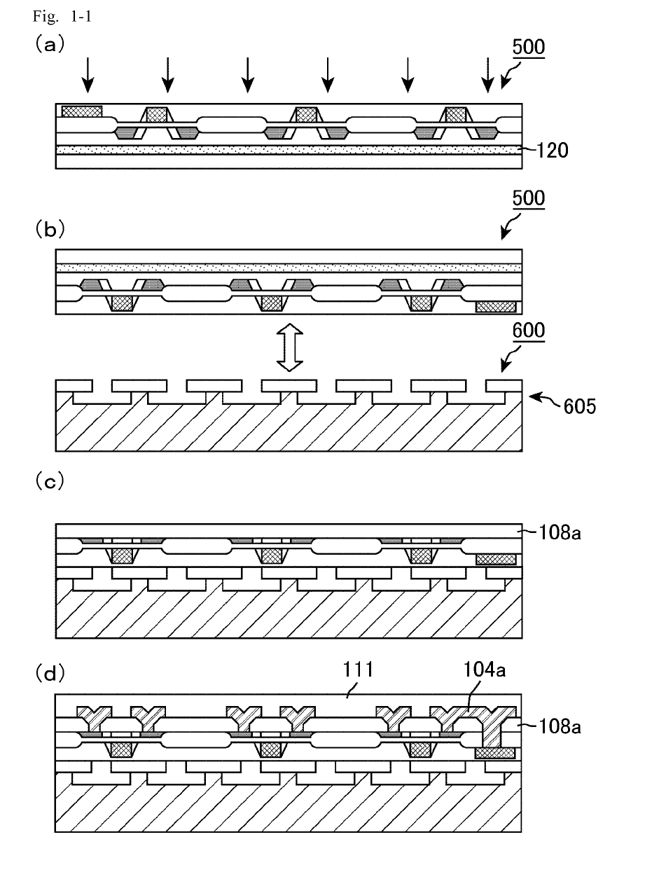

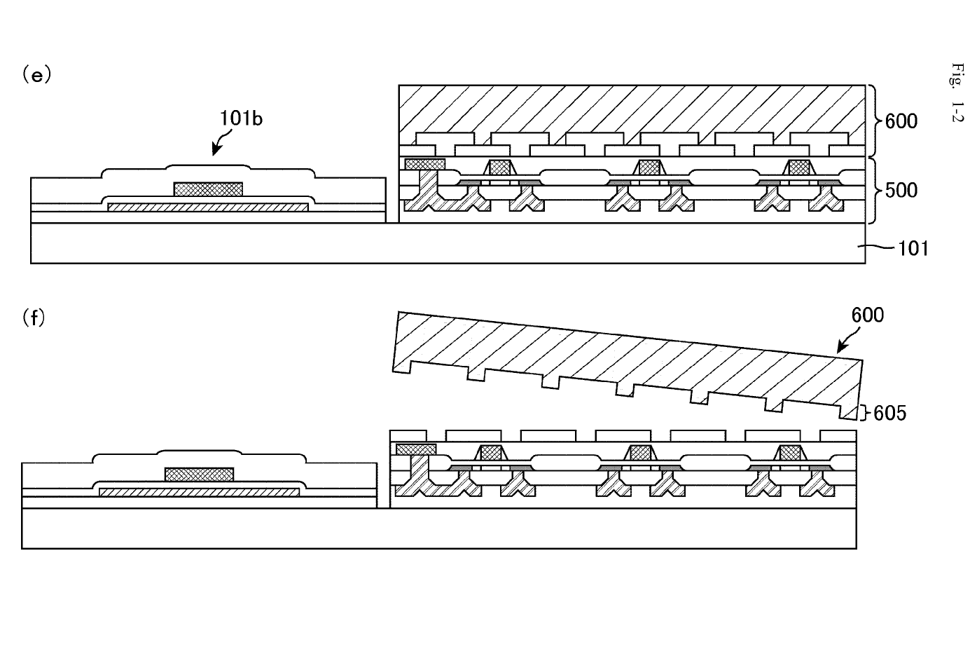

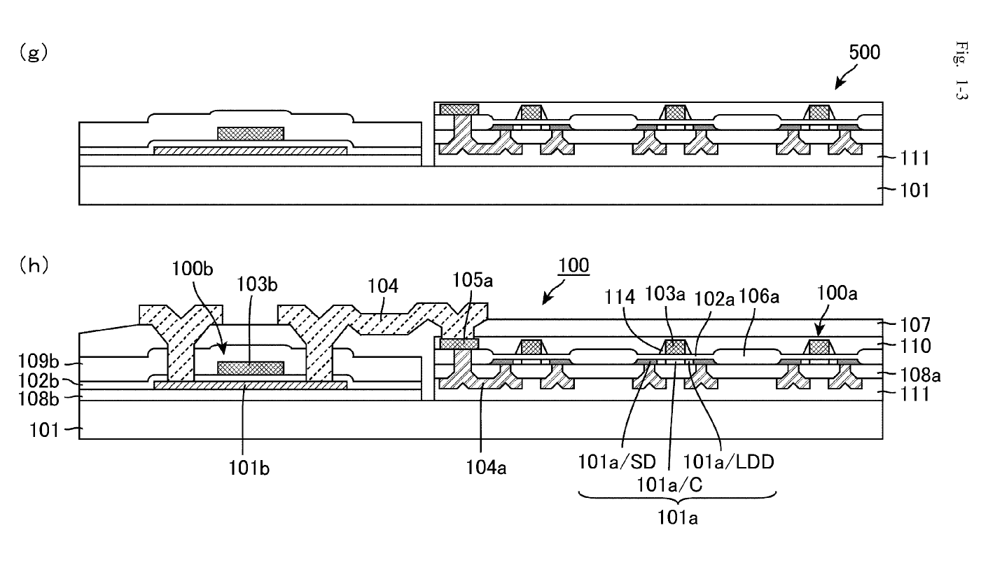

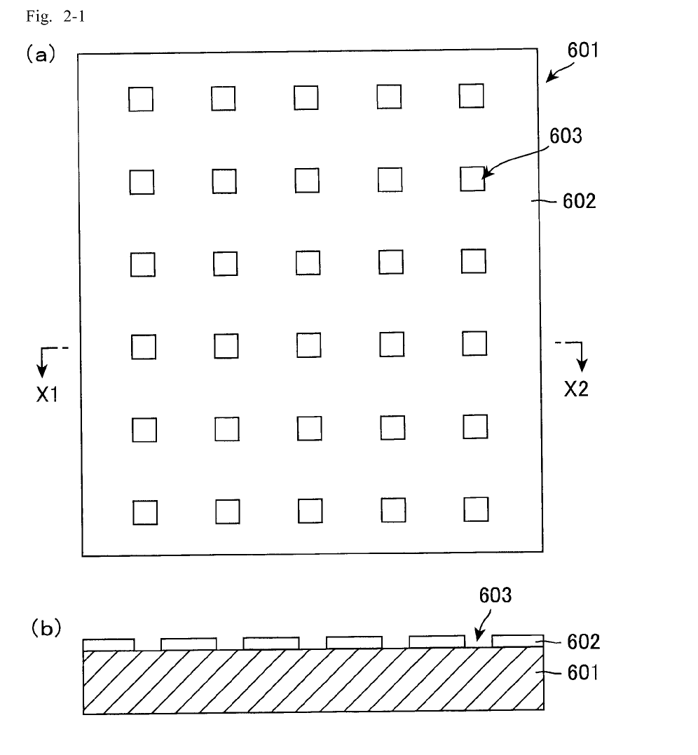

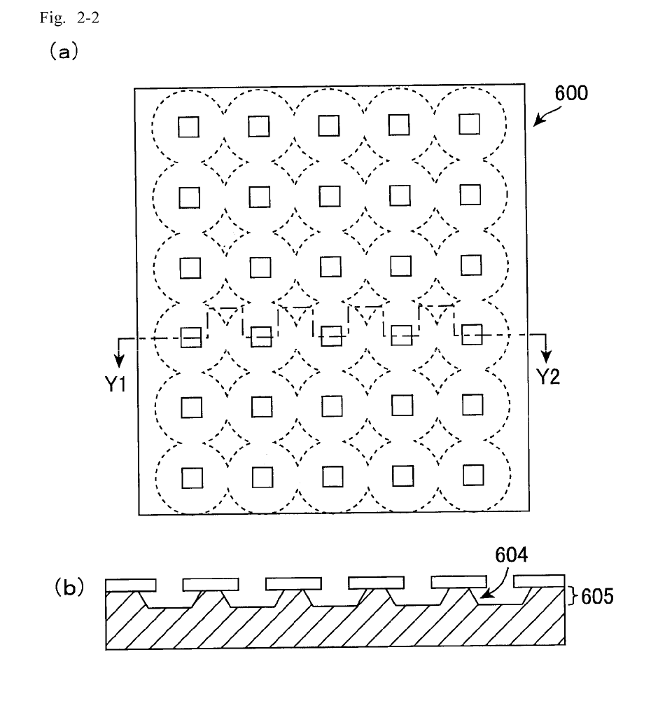

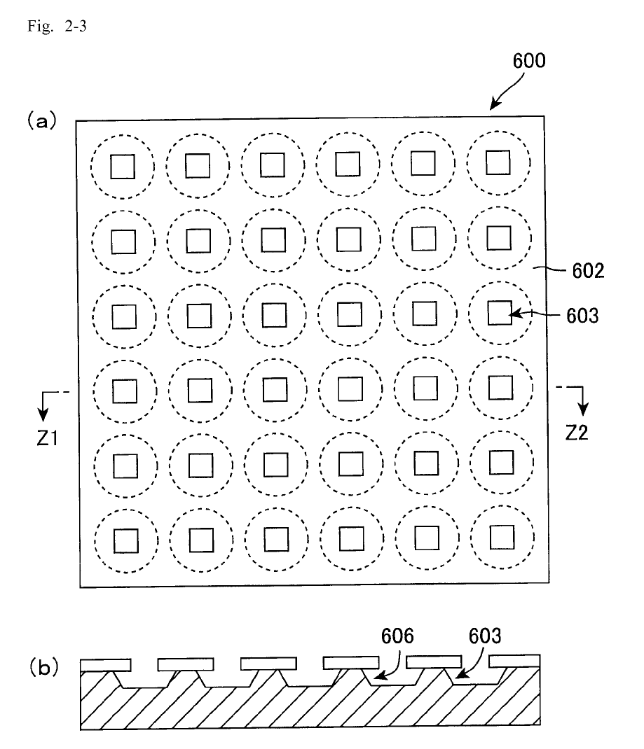

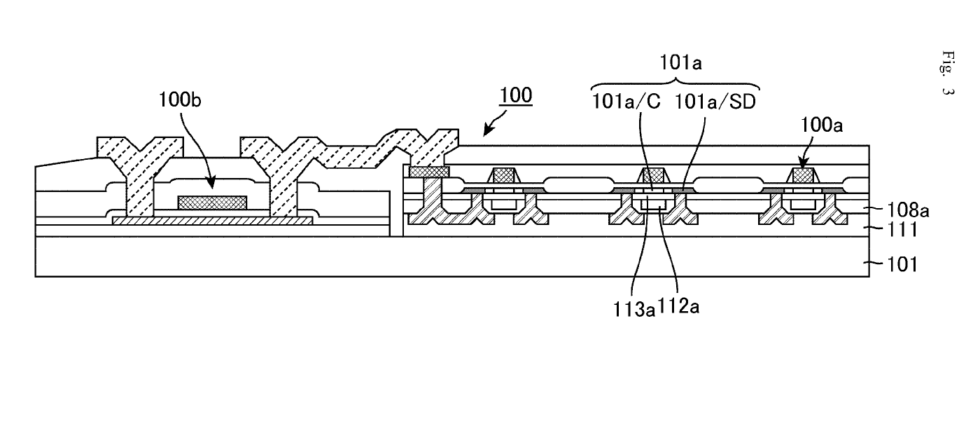

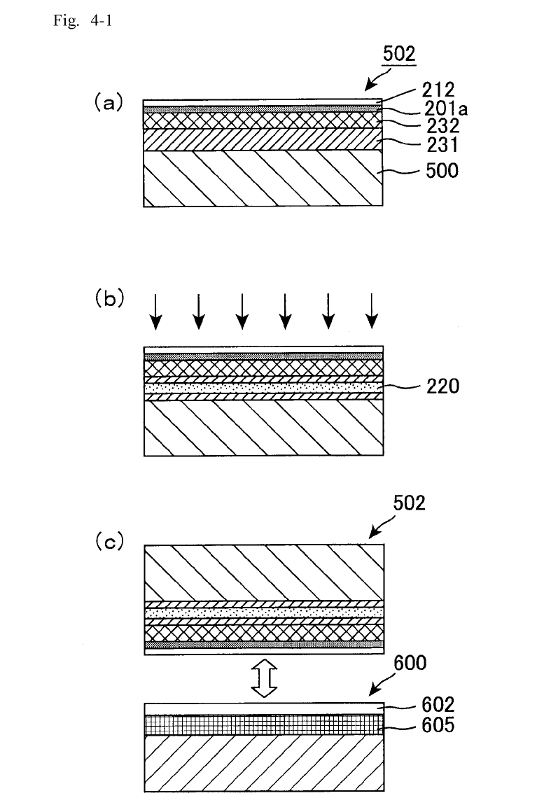

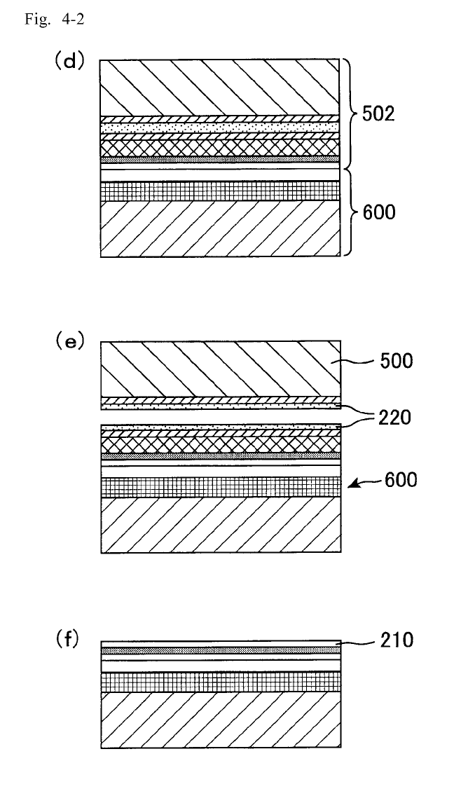

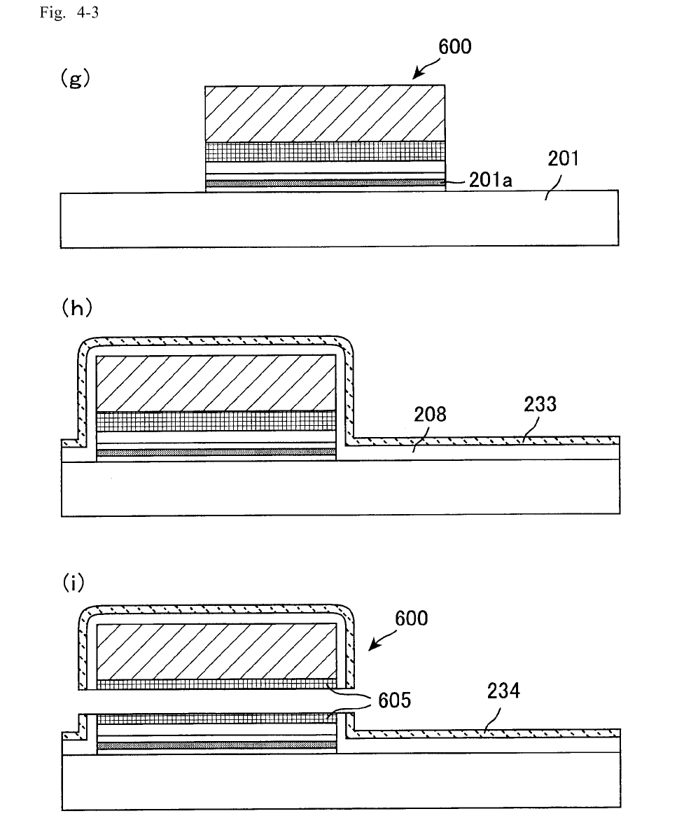

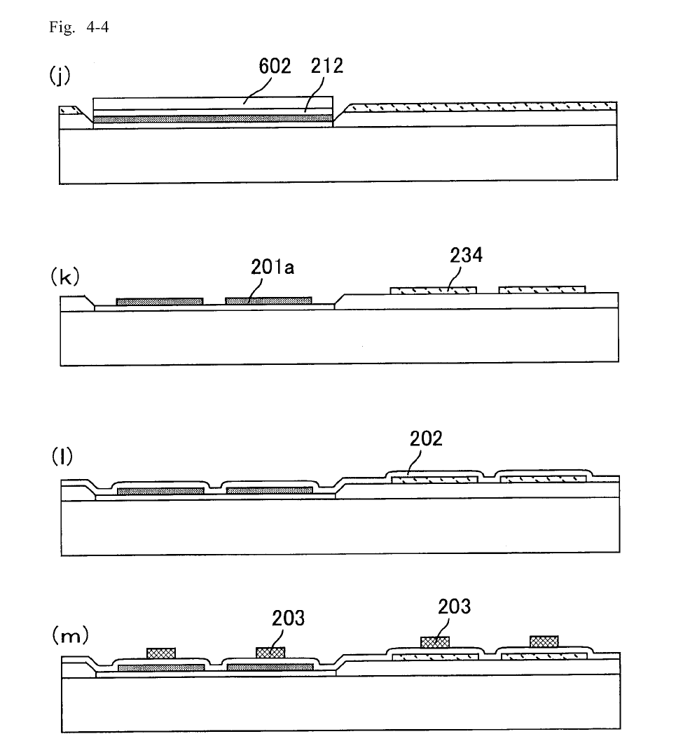

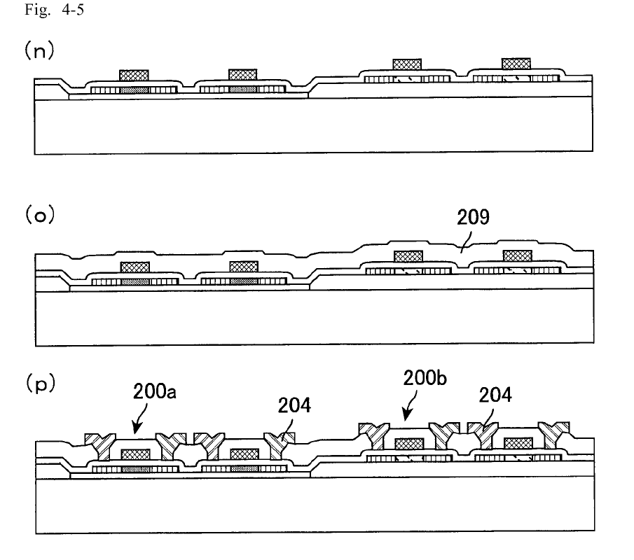

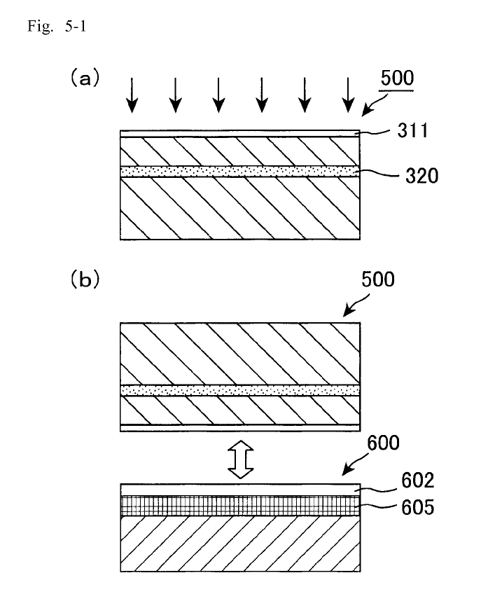

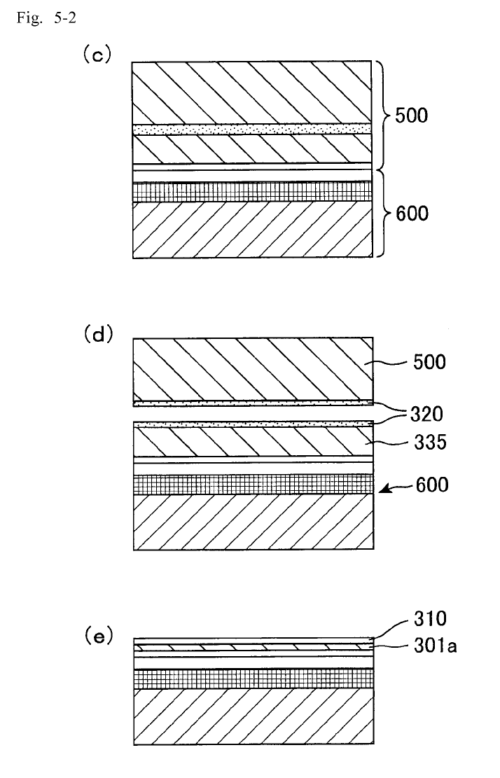

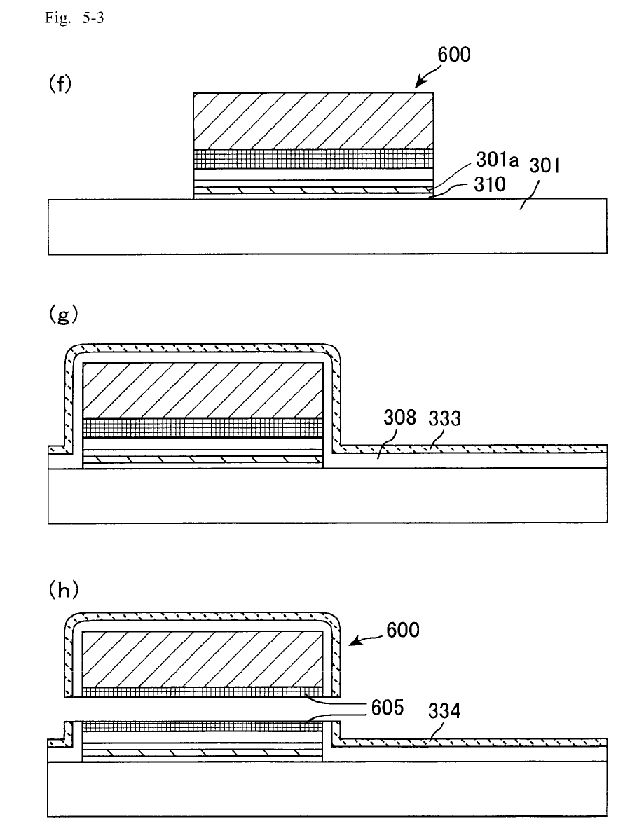

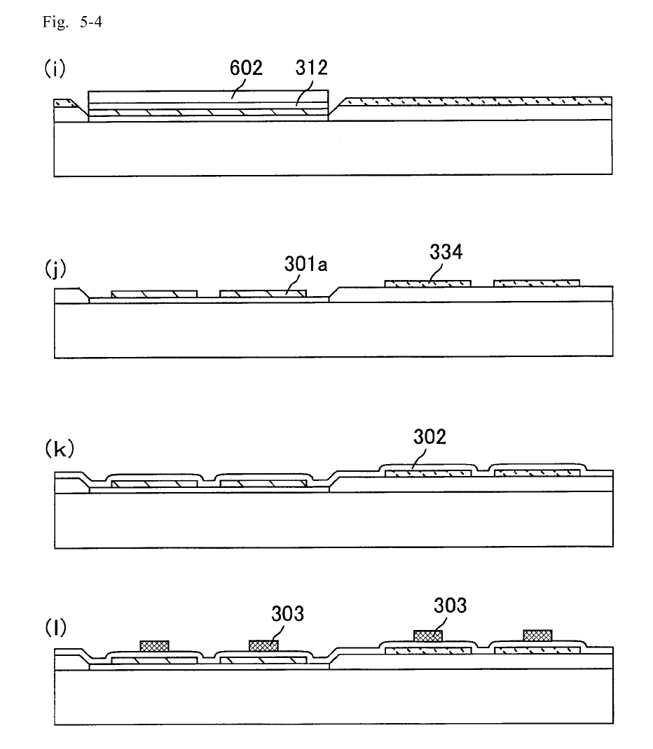

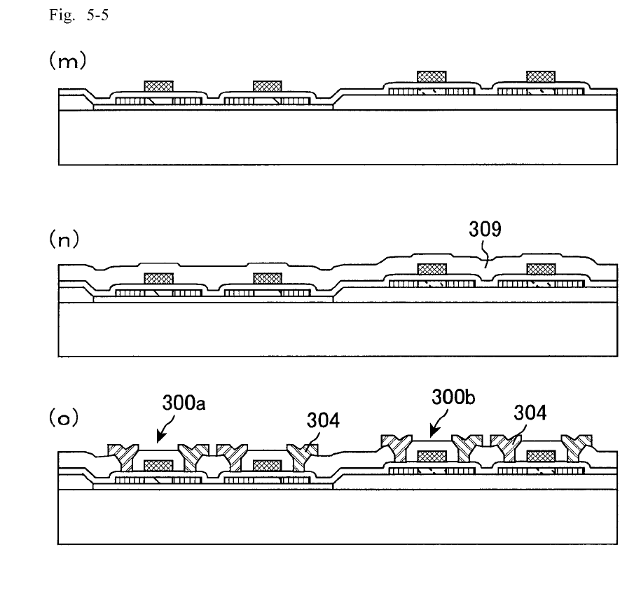

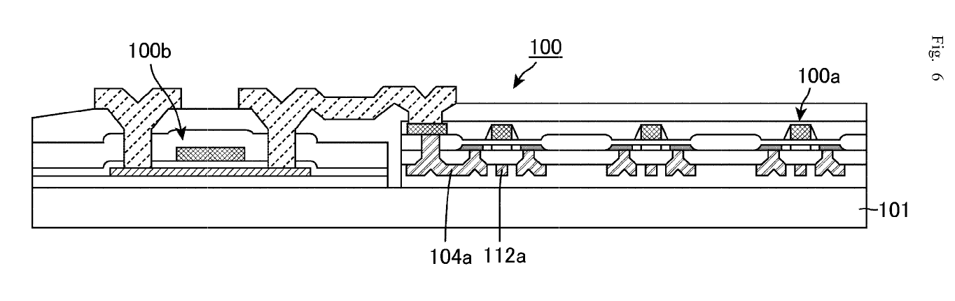

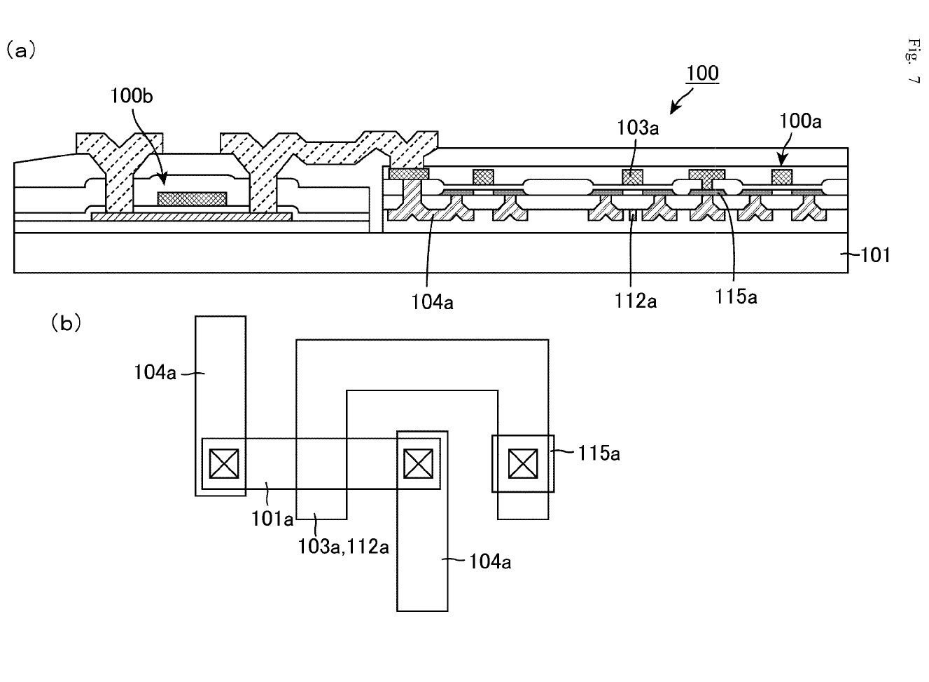

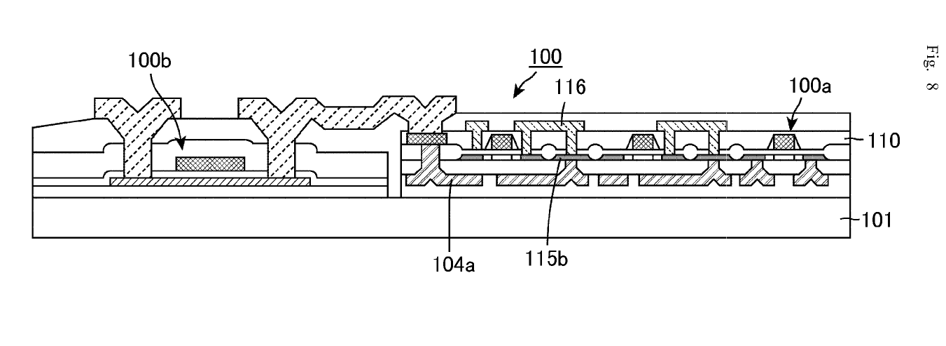

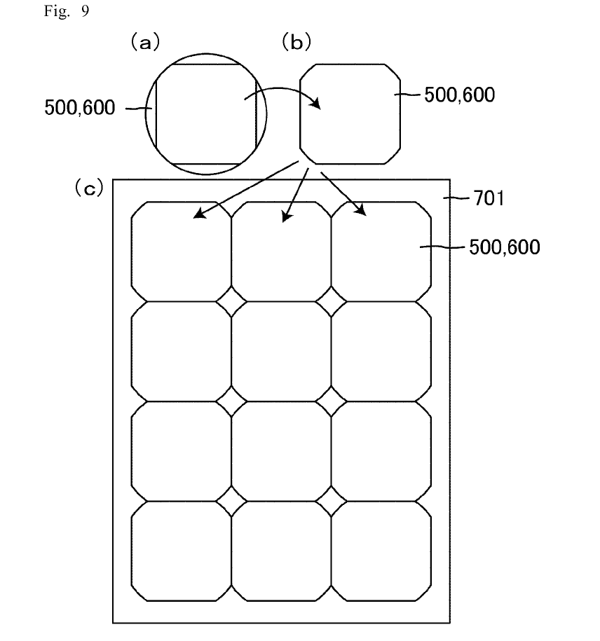

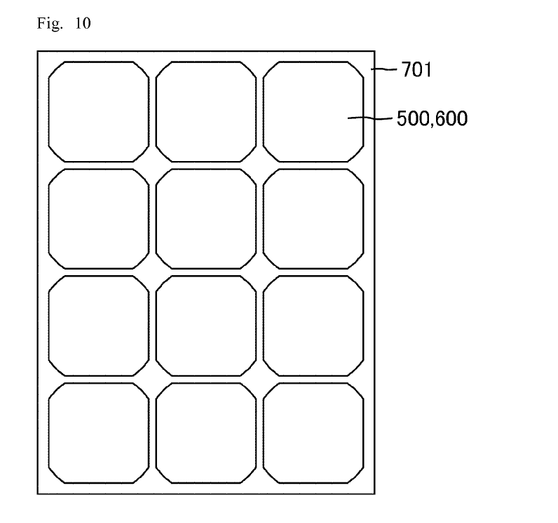

### EXPLANATION OF NUMERALS AND SYMBOLS

100: Semiconductor device
100a, 200a, 300a: Single-crystal Si TFT
100b, 200b, 300b: Non-single-crystal Si TFT
101, 201, 301: Insulating substrate
101a, 301a: single-crystal Si thin film
101a/C: Channel
101a/SD: Source-drain
101a/LDD: LDD region
101b: Non-single-crystal Si thin film
102a, 113a, 102b, 202, 302: Gate insulating film (gate oxide film)
103a, 112a, 103b, 203, 303: Gate electrode
104, 104a, 204, 304: Metal wiring
105a: Contact
106a: LOCOS oxide film
107: Interlayer flattening film
108a, 108b, 109b, 208, 209, 308, 309: Interlayer insulating film
110, 111, 210, 310: Flattening film
114: Side wall
115a, 115b: Connection
116: High heat-resistant wiring
201a: Strained Si layer
212, 312: SiO₂ film
120, 220, 320: Hydrogen ion-implanted portion (cleavage layer)
231: Graded layer
232: Buffer layer
233, 333: a-Si film
234, 334: Poly-Si film
335: Single-crystal Si layer
500: Single-crystal Si substrate (Si wafer)
502: Strained Si substrate
600: Intermediate substrate
601: Si wafer
311, 602: Thermal oxide film (bonding layer)
603: Opening
604: Columnar structure
605: Separation structure
606: Wall structure
701: Glass substrate

1. A production method of a semiconductor device including single-crystal semiconductor thin film-including single-crystal semiconductor elements on an insulating substrate,
the production method comprising a heat treatment step of subjecting a single-crystal semiconductor thin film to a heat treatment at 650° C. or higher,
the single-crystal semiconductor thin film including at least part of each one of single-crystal semiconductor elements and boded to an intermediate substrate with a heat-resistant temperature higher than that of the insulating substrate.

2. The production method according to claim 1,
further comprising: before the heat treatment step,
a first bonding step;
a semiconductor substrate-separating step; and
an element-dividing step, in this order,
wherein in the first bonding step,
a semiconductor substrate is bonded to the intermediate substrate,
the semiconductor substrate including: the at least part of each one of single-crystal semiconductor elements; and a cleavage layer including an implanted cleavage substance containing at least one of hydrogen ion and rare gas ion;
in the semiconductor substrate-separating step,
the semiconductor substrate is separated by cleavage of the cleavage layer by a heat treatment;
in the element-dividing step,
a remaining portion of the semiconductor substrate bonded to the intermediate substrate is thinned to give the single-crystal semiconductor thin film, and the semiconductor elements are divided; and
in the heat treatment step,
the single-crystal semiconductor thin film and the intermediate substrate undergo the heat treatment.

3. The production method according to claim 1,
further comprising:
a first flattening step;
a cleavage layer-forming step;
a first bonding step;
a semiconductor substrate-separating step;
an element-dividing step;
a second flattening step; and
a second bonding step, in this order,
wherein in the first flattening step,
a first flattening layer is formed on a semiconductor elements side-surface of a semiconductor substrate including the at least part of each one of the semiconductor elements;
in the cleavage layer-forming step,
a cleavage layer is formed by implanting a cleavage substance containing at least one of hydrogen ion and rare gas ion into the semiconductor substrate at a predetermined depth through the first flattening layer;
in the first bonding step,
the first flattening layer is bonded to the intermediate substrate;
in the semiconductor substrate-separating step,
the semiconductor substrate is separated by cleavage of the cleavage layer by a heat treatment;
in the element-dividing step,
a remaining portion of the semiconductor substrate bonded to the intermediate substrate is thinned to give the single-crystal semiconductor thin film, and the semiconductor elements are divided;
in the second flattening film,
a second flattening layer is formed on a surface opposite to an intermediate substrate side-surface of the single-crystal semiconductor thin film; and
in the second bonding step,
the second flattening layer is bonded to the insulating substrate, and
wherein the heat treatment step is performed between the element-dividing step and the second flattening step or after the second flattening step, and
in the heat treatment step,
the single-crystal semiconductor thin film and the intermediate substrate undergo the heat treatment.

4. The production method according to claim 1,
wherein the intermediate substrate includes a separation layer formed therein at a predetermined depth.

5. The production method according to claim 4,
wherein the intermediate substrate includes a bonding layer partially opened in a plurality of regions on a surface thereof, and
the separation layer has a structure in which part of the intermediate substrate is etched through the openings of the bonding layer.

6. The production method according to claim 4,
wherein the separation layer is a germanium-silicon alloy layer.

7. The production method according to claim 4,
further comprising an intermediate substrate-separating step of separating the intermediate substrate by cleavage of the separation layer.

8. The production method according to claim 1,
wherein the single-crystal semiconductor thin film contains strained silicon.

9. A production method of a single-crystal semiconductor thin film-including substrate including an insulating substrate and a single-crystal semiconductor thin film formed on the insulating substrate,
the production method comprising a heat treatment step of subjecting a single-crystal semiconductor thin film bonded to an intermediate substrate with a heat-resistant temperature higher than that of an insulating substrate to a heat treatment at 650° C. or higher.

10. The production method according to claim 9,
further comprising: before the heat treatment step,
a first bonding step;
a semiconductor substrate-separating step; and
a thinning step, in this order,
wherein in the first bonding step,
a semiconductor substrate including a cleavage layer including an implanted cleavage substance containing at least one of hydrogen ion and rare gas ion is bonded to the intermediate substrate;
in the semiconductor substrate-separating step,
the semiconductor substrate is separated by cleavage of the cleavage layer by a heat treatment; and
in the thinning step,
a remaining portion of the semiconductor substrate bonded to the intermediate substrate is thinned to give the single-crystal semiconductor thin film, and
wherein in the heat treatment step,
the single-crystal semiconductor thin film and the intermediate substrate undergo the heat treatment.

11. The production method according to claim 9, further comprising:
a cleavage layer-forming step;
a first bonding step;
a semiconductor substrate-separating step;
a thinning step;
a flattening step; and
a second bonding step, in this order,
wherein in the cleavage layer-forming step,
a cleavage layer is formed by implanting a cleavage substance containing at least one of hydrogen ion and rare gas ion into a semiconductor substrate at a predetermined depth;
in the first bonding step,
the semiconductor substrate is bonded to the intermediate substrate;
in the semiconductor substrate-separating step,
the semiconductor substrate is separated by cleavage of the cleavage layer by a heat treatment;
in the thinning step,
a remaining portion of the semiconductor substrate bonded to the intermediate substrate is thinned to give the single-crystal semiconductor thin film;
in the flattening step,
a surface opposite to the intermediate substrate side-surface of the single-crystal semiconductor thin film is flattened; and
in the second bonding step,
the flattening layer is bonded to the insulating substrate, and
wherein the heat treatment step is performed between the thinning step and the flattening step or after the flattening step, and
in the heat treatment step,
the single-crystal semiconductor thin film and the intermediate substrate undergo the heat treatment.

12. The production method according to claim 9,
wherein the intermediate substrate includes a separation layer formed therein at a predetermined depth.

13. The production method according to claim 12,
wherein the intermediate substrate includes a bonding layer partially opened in a plurality of regions on a surface thereof, and
the separation layer has a structure in which part of the intermediate substrate is etched through the openings of the bonding layer.

14. The production method according to claim 12,
wherein the separation layer is a germanium-silicon alloy layer.

15. The production method according to claim 12,
further comprising an intermediate substrate-separating step of separating the intermediate substrate by cleavage of the separation layer.

16. A semiconductor device comprising single-crystal semiconductor elements produced using a single-crystal semiconductor thin film-including substrate produced by the production method of claim 9.

17. A semiconductor device comprising single-crystal semiconductor thin film-including single-crystal semiconductor elements on an insulating substrate,
wherein the insulating substrate has a heat-resistant temperature of 600° C. or lower,
the single-crystal semiconductor elements are MOS transistors in which a first gate electrode self-aligning with a channel of the single-crystal semiconductor thin film and a side wall self-aligning with an LDD region of the single-crystal semiconductor thin film; a gate insulating film; and the single-crystal semiconductor thin film are stacked, and
the first gate electrode and the side wall are arranged in a layer upper than the single-crystal semiconductor thin film.

18. The semiconductor device according to claim 17,
wherein an activation ratio of acceptors in the single-crystal semiconductor thin film is 50% or larger.

19. The semiconductor device according to claim 17,
wherein the insulating substrate has a strain point of 800° C. or lower.

20. The semiconductor device according to claim 17,
wherein the insulating substrate is a glass substrate.

21. The semiconductor device according to claim 17,
wherein the insulating substrate is a metal substrate including an insulating layer formed thereon.

22. The semiconductor device according to claim 17,
wherein the insulating substrate is a resin substrate including an insulating layer formed thereon.

23. The semiconductor device according to claim 17,
wherein the insulating substrate is a resin substrate.

24. The semiconductor device according to claim 23,
wherein the single-crystal semiconductor elements are bonded to the insulating substrate with a resin adhesive therebetween.

25. The semiconductor device according to claim 17,
wherein a subthreshold slope of the single-crystal semiconductor elements is 75 mV/dec or smaller.

26. The semiconductor device according to claim 17,
further comprising non-single-crystal semiconductor thin film-including non-single-crystal semiconductor elements on the insulating substrate.

27. The semiconductor device according to claim 17,
wherein the single-crystal semiconductor elements further includes a second gate electrode formed on an insulating substrate side of the single-crystal semiconductor thin film.

28. The semiconductor device according to claim 27,
wherein the single-crystal semiconductor elements include a PMOS transistor and a NMOS transistor, and
the second gate electrode is independent between the PMOS transistor and the NMOS transistor.

29. The semiconductor device according to claim 27,
wherein the second gate electrode does not self-align with the channel of the single-crystal semiconductor thin film.

30. The semiconductor device according to claim 27,
wherein the single-crystal semiconductor elements further include a wiring arranged on the insulating substrate side of the single-crystal semiconductor thin film, and
the second gate electrode and the wiring are positioned in the same layer.

31. The semiconductor device according to claim 27,
wherein the second gate electrode is connected to the first gate electrode.

32. The semiconductor device according to claim 17,
wherein a bonded interface between the insulating substrate and the single-crystal semiconductor elements contains SiO₂—SiO₂ bond or SiO₂-glass bond.

33. The semiconductor device according to claim 17,
wherein the single-crystal semiconductor thin film contains strained silicon.

34. The semiconductor device according to claim 17,
wherein the single-crystal semiconductor elements include a PMOS transistor, and
the PMOS transistor includes a strained (100) silicon film and has a compressive stress.

35. The semiconductor device according to claim 17,
wherein the single-crystal semiconductor elements include an NMOS transistor, and
the NMOS transistor has a tensile stress.

36. The semiconductor device according to claim 17,
wherein the single-crystal semiconductor thin film contains at least one semiconductor selected from the group consisting of germanium, silicon carbide, and gallium nitride.

37. The semiconductor device according to claim 17,
wherein the insulating substrate is larger than a region where the single-crystal semiconductor elements are arranged.

38. The semiconductor device according to claim 17,
further comprising a first wiring containing a low-resistance metal material on an insulating substrate side of the single-crystal semiconductor thin film.

39. The semiconductor device according to claim 38,
further comprising a second wiring arranged in a layer upper than the single-crystal semiconductor thin film and in contact with at least part of the single-crystal semiconductor thin film, and
the second wiring contains a metal material with a heat-resistant temperature of 650° C. or higher.

40. A single-crystal semiconductor thin film-including substrate including an insulating substrate and a single-crystal semiconductor thin film formed on the insulating substrate,
wherein the insulating substrate has a heat-resistant temperature of 600° C. or lower, and
the single-crystal semiconductor thin film has an average surface roughness Ra of 5 nm or smaller.

41. The single-crystal semiconductor thin film-including substrate according to claim 40,
wherein a variation in thickness of the single-crystal semiconductor film is 10% or smaller.

42. The single-crystal semiconductor thin film-including substrate according to claim 40,
wherein the insulating substrate has a strain point of 800° C. or lower.

43. The single-crystal semiconductor thin film-including substrate according to claim 40,
wherein the insulating substrate is a glass substrate.

44. The single-crystal semiconductor thin film-including substrate according to claim 40,
wherein the insulating substrate is a metal substrate including an insulating layer formed thereon.

45. The single-crystal semiconductor thin film-including substrate according to claim 40,
wherein the insulating substrate is a resin substrate including an insulating layer formed thereon.

46. The single-crystal semiconductor thin film-including substrate according to claim 40,
wherein the insulating substrate is a resin substrate.

47. The semiconductor device according to claim 46,
wherein the single-crystal semiconductor thin film is bonded to the insulating substrate with a resin adhesive therebetween.

48. The single-crystal semiconductor thin film-including substrate according to claim 40,
further comprising a non-single-crystal semiconductor thin film on the insulating substrate.

49. The single-crystal semiconductor thin film-including substrate according to claim 40,
wherein a bonded interface between the insulating substrate and the single-crystal semiconductor thin film contains SiO₂—SiO₂ bond or SiO₂-glass bond.

50. The single-crystal semiconductor thin film-including substrate according to claim 40,
wherein the single-crystal semiconductor thin film contains strained silicon.

51. The single-crystal semiconductor thin film-including substrate according to claim 40,
wherein the single-crystal semiconductor thin film contains at least one semiconductor selected from the group consisting of germanium, silicon carbide, and gallium nitride.

52. The single-crystal semiconductor thin film-including substrate according to claim 40,
wherein the insulating substrate is larger than the single-crystal semiconductor thin film.

53. The single-crystal semiconductor thin film-including substrate according to claim 52,
comprising a plurality of the single-crystal semiconductor thin films, and
the single-crystal semiconductor thin films are closely arranged in an island pattern in a plane of the insulating substrate.

54. A semiconductor device comprising single-crystal semiconductor elements produced using the single-crystal semiconductor thin film-including substrate according to claim 40.
